(19) United States
(12) Patent Application Publication
(10) Pub. No.: US 2025/0337412 A1
(43) Pub. Date: Oct. 30, 2025

(54) MANAGING VARIATION IN PHASE-LOCKED LOOP (PLL) BANDWIDTH, AND RELATED METHODS AND APPARATUSES

(71) Applicant: Microchip Technology Incorporated, Chandler, AZ (US)

(72) Inventors: Siddhartha Hazra, Durgapur (IN); Hormoz Djahanshahi, Port Moody (CA)

(21) Appl. No.: 19/192,167

(22) Filed: Apr. 28, 2025

(30) Foreign Application Priority Data
Apr. 26, 2024 (IN) 202441033435

(51) Int. Cl. H03K 19/003; H03L 7/18

(52) U.S. Cl. CPC H03K 19/00369; H03L 7/18

(57) ABSTRACT

An apparatus includes a phase-locked loop (PLL) circuit and a logic circuit. The logic circuit may manage, via one or more programmable operating parameters of the PLL circuit, PLL bandwidth variation exhibited by the PLL circuit due to variations in its manufacturing process (P), supply voltage (V) or temperature (T), i.e., PVT variations exhibited by the PLL circuit.

### CROSS-REFERENCE TO RELATED APPLICATIONS

This application claims the benefit of the filing date of Indian Provisional Patent Application No. 202441033435, filed Apr. 26, 2024, for “SYSTEM AND METHOD FOR PHASE-LOCKED LOOP (PLL) BANDWIDTH CALIBRATION.”

### FIELD

One or more examples relate, generally, to phase-locked loop (PLL) circuits and calibration techniques. More specifically, one or more examples relate to methods and apparatus for adjusting PLL operating parameters—such as charge pump current and related settings—to manage variation in PLL bandwidth from targets.

### BACKGROUND

Phase-locked loop (PLL) circuits are widely employed in modern electronic systems for frequency synthesis, clock generation, and signal synchronization. A typical PLL comprises a voltage-controlled oscillator (VCO), a phase-frequency detector (PFD), a charge pump, and a loop filter, which together establish a closed-loop control system that locks the VCO output frequency to a reference frequency. PLL circuits are implemented in a variety of configurations including analog, digital, and mixed-signal (hybrid) architectures to meet diverse performance and integration requirements. VCO circuits may be implemented as LC oscillator or ring oscillator to meet frequency tuning range and jitter requirements.

Modern PLL technologies incorporate programmable and digitally controlled elements to allow fine-tuning of operating parameters. These elements enhance flexibility and allow the circuits to adapt to varying conditions by adjusting parameters such as charge pump current, loop filter response, and VCO control.

### BRIEF DESCRIPTION OF THE DRAWINGS

To easily identify the discussion of any particular element or act, the most significant digit or digits in a reference number refer to the figure number in which that element is first introduced.

FIG. 1 is a block diagram depicting a PLL system that includes a voltage and temperature (VT) aware bandwidth calibration engine, in accordance with one or more examples.

FIG. 2 is a schematic diagram depicting a circuit, which is an example of an LC-based voltage-controlled oscillator (VCO) that receives both coarse (P-Bits) and fine (Vcontrol) frequency tuning, in accordance with one or more examples.

FIG. 3 is a flow diagram depicting a process to calibrate a PLL to maintain a stable PLL bandwidth in view of potential PLL bandwidth variation due to variation in VCO gain Kvco, in accordance with one or more examples.

FIG. 4 is a flow diagram depicting a process to measure VCO gain (Kvco) in an open-loop mode, in accordance with one or more examples.

FIG. 5 is a flow diagram depicting a process to determine the number of active charge pump (CP) stages and the unit charge pump current (Unit_Icp) in a phase-locked loop (PLL), in accordance with one or more examples.

FIG. 6 is a chart depicting a relationship between PLL bandwidth and temperature.

FIG. 7 is a flow diagram depicting a process to measure VCO gain (Kvco) and apply a temperature-based scaling to measured Kvco to account for T-drift, in accordance with one or more examples.

FIG. 8 is a conceptual diagram depicting a plot graph of VCO gain (Kvco) versus temperature and shows how the measured Kvco at a particular temperature can be translated or compared to a nominal Kvco_typ at a typical temperature (Ttyp).

FIG. 9 depicts three conceptual graphs illustrating different methods of approximating a non-linear relationship between VCO gain (Kvco) and an independent variable, such as temperature or supply voltage, in accordance with one or more examples.

FIG. 10 shows two related flow diagrams-process on the left, which depicts creating a lookup table (LUT) containing values of charge pump current (Icp) for different ranges of Kvco variation from target (Del_Kvco), and process on the right, which depicts using the LUT at runtime to set the PLL's bandwidth parameters, respectively in accordance with one or more examples.

FIG. 11 is a flow diagram depicting a process for setting a new total charge pump current (Icp_new) and determining how many charge pump stages (CP_Stage_new) should be active to compensate for an observed difference between the measured or desired Icp value and a baseline value.

FIG. 12 depicts a conceptual diagram of a graph that illustrates how a VCO gain function, denoted Kvco(T) on the vertical axis, can be approximated by two linear segments when measured at three distinct temperature points, T₁, T₂, T₃ on the horizontal axis, and further depicts a flow diagram depicting a process to determine a translated VCO gain (e.g., a temperature-scaled VCO gain (Kvco′), without limitation), and store the resulting gain deviation from target in a piecewise linear or multi-point context.

FIG. 13 is a block diagram of circuitry that, in some examples, may be used to implement various functions, operations, acts, processes, or methods disclosed herein.

### DETAILED DESCRIPTION

In the following detailed description, reference is made to the accompanying drawings, which form a part hereof, and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example of this disclosure to the specified components, steps, operations, acts, features, functions, or the like.

It will be readily understood that the components of the examples as generally described herein and illustrated in the drawing could be arranged and designed in a wide variety of different configurations. Thus, the following description of various examples is not intended to limit the scope of the present disclosure, but is merely representative of various examples. While the various aspects of the examples may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths, and the present disclosure may be implemented on any number of data signals including a single data signal.

The various illustrative logical blocks, modules, and circuits described in connection with the examples disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose determiner including a processor is considered a special-purpose determiner while the general-purpose determiner executes computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on determiner-readable media. Determiner-readable media includes both determiner storage media and communication media including any medium that facilitates transfer of a determiner program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description the term “coupled,” and derivatives thereof, may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

As used herein, the terms “assert,” “de-assert” and derivatives thereof used in reference to a pin, means, respectively, to assert or de-assert a signal associated with the pin (e.g., a signal specifically assigned to the pin or a signal to which the pin is specifically assigned, without limitation).

Input jitter is the variations or disturbances in the phase or frequency of an input signal, which in a phase-locked loop (PLL) is the reference clock. Input jitter can reduce the integrity and reliability of the PLL output, affecting performance, causing errors, and potentially leading to system failures.

The jitter transfer function of a PLL describes the frequency response of the PLL to phase noise or jitter from input reference clock and intrinsic noise sources. The jitter transfer function provides a quantitative measure of the PLL's ability to filter or suppress input jitter at different frequencies and how it translates to the PLL output jitter. Sometimes a PLL jitter transfer function exhibits a rise or peak in its magnitude response at specific frequencies. The peak represents a temporary increase in the gain of the system, which can lead to an amplification of the input jitter at those specific frequencies.

The ability of a PLL to suppress or accommodate input jitter depends on its closed-loop bandwidth (“PLL bandwidth”) and the design of its loop filter. PLL bandwidth is the range of frequencies (“frequency range”) over which a PLL can effectively track changes in an input signal's phase or frequency. PLL bandwidth defines how quickly the PLL responds to changes in the input signal and corrects any differences between the input signal and the PLL's output.

A PLL with narrow PLL bandwidth may filter out high-frequency input jitter effectively but might slow down the PLL's response to changes in the reference clock frequency. Conversely, a PLL with a wider PLL bandwidth may respond faster but could also allow more input jitter to pass through to the output.

PLL bandwidth is a key metric for PLL performance that directly affects stability, jitter, and compliance with standards. So, it is desirable that PLL bandwidth be stable and well defined. PLL loop parameters, such as charge pump current, loop filter resistance and voltage-controlled oscillator (VCO) gain (Kvco), define the performance characteristics of a PLL and control its bandwidth (BW). These PLL parameters are subject to process, supply voltage and temperature variations (PVT), and define the min-to-max range of the PLL bandwidth across PVT. PLL bandwidth variation is the amount by which the actual bandwidth of a PLL (during closed-loop operation) deviates from target values or specified ranges (e.g., its intended design value or range, without limitation) as a result of inherent variability in the VCO gain, charge pump current, and loop filter resistance.

New applications may require a tight spread (range from min to max) in the PLL bandwidth to keep PLL performance under control. Further, some standards require explicit bandwidth setting (min/max limits) and testing of bandwidth to validate compliance.

A traditional approach is to measure the PLL bandwidth in a field test or during a production test and trim the bandwidth or calibrate for the bandwidth, directly. But measurement of PLL bandwidth, directly, is very complex because it is a small signal parameter, and measuring it in the field typically requires expensive, specialty hardware.

Another traditional approach is to calibrate the VCO element directly to compensate for Kvco variation (e.g., Kvco PVT variation, also referred to herein as “ΔKvco,” without limitation). Kvco variation is a substantial contributor to PLL bandwidth variation, and PLL bandwidth variation is generally proportional to Kvco variation. Stated another way, there is a correlative relationship between Kvco variation and PLL bandwidth variation.

Kvco measurement is simpler compared to PLL bandwidth measurement. However, there is a performance penalty from setting (e.g., trimming or calibrating, without limitation) Kvco using the VCO elements because some mechanism (e.g., a programmable switches and/or additional tuning elements within the VCO elements, without limitation) is required to set Kvco, and the VCO is a sensitive block in ways that impact not only the PLL bandwidth but also degrade system performance (e.g., in terms of jitter, without limitation). Further, Kvco measurement should be done at the desired frequency of operation, so VCO frequency tuning calibration precedes the Kvco measurement. Setting the Kvco using VCO elements directly affects the tuned frequency, so VCO frequency tuning calibration is repeated after the Kvco is set. This makes that process iterative (measure, change, measure again, and so on and so forth) and time-consuming.

One or more examples relate, generally, to calibration of phase-locked loop (PLL) bandwidth in electronic circuits. Tight control over the PLL's closed-loop bandwidth may be achieved by compensating for process, supply voltage, and temperature (PVT) variations. Rather than directly tuning VCO elements (which can adversely affect its performance parameters such as phase noise and maximum operating frequency), the programmability of the charge pump current (Icp) is utilized as discussed herein to compensate for variations in the VCO gain (Kvco).

Instead of attempting to directly control Kvco—which would involve invasive changes to the VCO structure—actual Kvco is measured (e.g., using a Δf/ΔVcontrol technique at a calibrated frequency, without limitation) and measured Kvco is compared with a predetermined value that represents a target value (“target Kvco”) and the deviation (“ΔKvco”) is determined. In one or more examples, ΔKvco may be determined as the difference between measured Kvco and target Kvco, or it may be further processed—such as by scaling or applying a polynomial correction—to account for non-linear behavior and VT (supply voltage and temperature) dependencies, as discussed herein.

ΔKvco represents an estimate of Kvco variation, from a target Kvco, under the specific startup conditions (PVT). Given that PLL bandwidth is proportional to the product of Icp×Kvco, setting Icp to compensate for Kvco variation (e.g., reduce effect from, or influence of, Kvco variation, without limitation), reduces PLL bandwidth variation. The charge pump current Icp can be adjusted proportionally in the opposite direction to ΔKvco, such that the product Icp×Kvco remains approximately constant, thereby stabilizing the PLL bandwidth without altering the VCO's internal characteristics. Accordingly, in one or more examples, ΔKvco is used to determine a new target for the total charge pump current Icp, and the total charge pump current Icp (the terms “total charge pump current” and “charge pump current” are used interchangeably herein to mean “total charge pump current”) is set to the new target Icp.

One or more examples relate, generally, to configuring total charge pump current Icp to compensate for Kvco variation. In one or more examples, total charge pump current Icp of a charge pump may be configured by setting one or more of unit charge pump current, number of charge pump stages, or reference voltage Vref used to generate the charge pump current in the PLL.

Charge pump current Icp is the amount of current that a charge pump circuit delivers to, or draws from, the loop filter in a PLL during phase/frequency correction time in every reference clock cycle. Charge pump current is an important parameter for adjusting the voltage across the loop filter, which in turn controls the frequency (f) of the VCO based on the phase difference detected between the input reference clock and the VCO output (or its frequency divided version) clock. Charge pump current Icp is a key parameter (e.g., a parameter that has significant influence on performance, functionality, and/or ability to meet intended purpose, without limitation) in PLL designs and has programmability implemented as a typical (e.g., best, without limitation) practice in PLL designs.

A charge pump may be composed of one or more discrete charge pump stages. Respective charge pump stages contribute a specific, quantifiable amount of current to the total charge pump current Icp, referred to herein as the “unit charge pump current Iunit.” Assuming respective charge pump stages exhibit uniform unit charge pump current Iunit, the total charge pump current Icp may be expressed as the number of active charge pump stages (n) multiplied by the unit charge pump current (Iunit): Icp=n×Iunit.

Iunit is the smallest increment of current that the charge pump can deliver to, or draw from, a loop filter. For example, if a charge pump is designed to deliver a maximum of 10 mA and consists of 10 stages, each stage might deliver 1 mA when activated.

The unit charge pump current Iunit may be expressed as a reference voltage (Vref) divided by a programmable resistance internal to the charge pump (Rinternal): Iunit=Vref/Rinternal. Reference voltage Vref is a key parameter in charge pump used in PLL designs. Vref serves as a reference voltage that at least partially determines the magnitude of the charge pump current Icp. The charge pump current Icp is proportional to Vref. Respective charge pump stages use the same Vref to ensure consistent behavior across all the charge pump stages. This uniformity helps maintain predictable and linear responses, as a non-limiting example, as different charge pump stages are activated or deactivated.

The internal resistance Rinternal is an explicit resistor specific to the charge pump design. Internal resistance Rinternal typically is not a standard parameter, but may be directly set (e.g., programmed, without limitation) in PLL designs.

Reference voltage Vref at least partially determines the charge pump current Icp. The internal resistance Rinternal can be realized, in design, as a multiple or fraction (k) of the loop-filter resistance Rp. Therefore, the unit charge pump current Iunit may be expressed in terms of the reference voltage Vref and the loop-filter resistance Rp as Iunit=Vref/(k×Rp). The loop-filter resistor is a component of the loop filter, and loop-filter resistance Rp at least partially defines the loop filter's behavior and the overall dynamics of the PLL, and so shapes the response of the PLL to phase differences between the input reference clock and the VCO output (or its frequency divided version) clock.

Since total charge pump current Icp is the product of the unit charge pump current and the number of active charge pump stages, the total charge pump current can be expressed as Icp=n×Vref/(k×Rp). Thus, Icp is at least partially based on the reference voltage Vref, the loop-filter resistance Rp, and the number of active charge pump stages n.

The change in the control voltage (ΔVcontrol) caused by Icp flowing through Rp can be expressed as ΔVcontrol=Icp×Rp. Vcontrol influences the VCO's output frequency, and the sensitivity of the frequency change in response to changes in Vcontrol is the gain Kvco. So, Kvco is correlated (e.g., proportional to, without limitation) Icp×Rp. As noted above, PLL bandwidth variation is correlated with (e.g., proportional to, without limitation) Kvco variation, so PLL bandwidth variation is correlated with Icp×Rp, which may be rewritten as the number of charge pump stages multiplied by the reference voltage: n×Vref/k. This makes the PLL bandwidth variation independent of PVT variation of Rp.

In one or more examples, the reference voltage Vref is generated from a bandgap voltage generator or a regulator, which are trimmable and have temperature compensation, and so may exhibit limited (e.g., about 3% to 5%, inclusive, without limitation) PVT variation. Once set, the number of active charge pump stages, n, and the multiplication factor, k, are fixed integer quantities or constants that exhibit no PVT variation.

Traditional approaches either neglect post-calibration supply voltage and temperature drift or require complex measurement hardware to track such changes. This may result in a PLL whose performance may drift significantly over its operating range, jeopardizing stability, and compliance with stringent standards.

One or more examples relate to supply voltage and temperature (VT) aware calibration of PLL bandwidth. A VT-aware calibration logic uses start-up supply voltage and temperature information (e.g., measurements captured by on chip sensors at startup and provided to the VT-aware calibration logic, without limitation) with a one-time Kvco measurement (e.g., performed via a two-point or multi-point coefficient measurement process discussed herein, without limitation) to determine a target charge pump current Icp that compensates for Kvco variation and PLL bandwidth variation due to VT drift. In one or more examples, the calibration algorithm applies either a linear or a second-order polynomial approximation (with coefficients stored in a lookup table) to predict the VT drift.

A person having ordinary skill in the art will appreciate many benefits and advantages of the numerous examples discussed herein. Non-limiting examples include one or more of: VCO performance is not compromised, reduces PVT variation of charge pump current Icp by design and uses charge pump current Icp to compensate for Kvco variation, and thereby the PLL bandwidth variation; does not require specific hardware inside the VCO element for programmability of Kvco—no impact on Fmax (maximum operating frequency) of a PLL, and negligible impact on jitter performance; quicker as compared to measuring and setting Kvco directly; simpler than measuring PLL bandwidth directly.

Kvco depends on the target operating frequency of the PLL. In one or more examples, a one-time VCO frequency calibration is performed to establish the target operating frequency prior to executing any bandwidth calibration. Once the VCO is locked to the desired frequency, a logic circuit may apply bandwidth adjustments—such as measuring the Kvco and modifying the total charge pump current, without limitation—without requiring additional frequency calibrations after each bandwidth adjustment action. Notably, in traditional approaches to bandwidth adjustment, such as those discussed above, changes to the VCO necessitate a frequency calibration before and/or after respective Kvco trimming or calibration iterations.

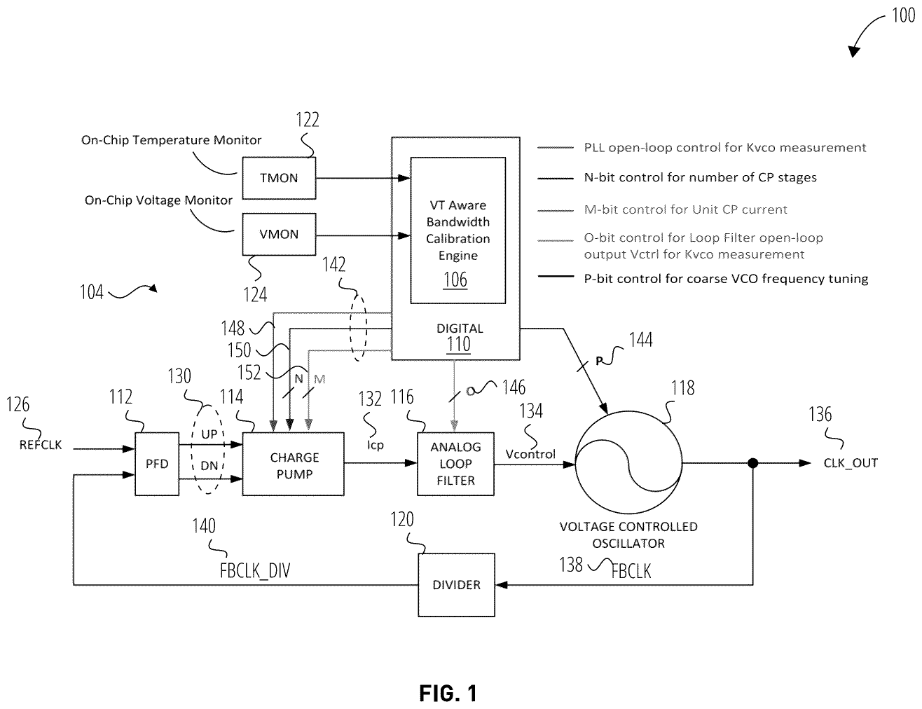

FIG. 1 is a block diagram depicting a PLL system that includes a voltage and temperature (VT) aware bandwidth calibration engine, in accordance with one or more examples.

PLL system 100 implements a phase-locked loop 104 with bandwidth calibration engine 106. Notably, PLL system 100 is capable of an open-loop calibration where parameters—such as charge pump current and VCO control settings—are measured and set. Such calibration may incorporate an optional adjustment for anticipated post-calibration drift (e.g., due to supply voltage or temperature changes, without limitation), as discussed below. The PLL system 100 is also capable of closed-loop operation, where PLL system 100 (and more specifically, phase-locked loop 104) utilizes the parameters established during the open-loop calibration.

An on-chip temperature monitor (TMON) 122 and an on-chip supply voltage monitor (VMON) 124 provide real-time measurements of the ambient temperature and supply voltage, respectively, to the bandwidth calibration engine 106. In certain implementations, these measurements are obtained at device startup and may, optionally, be periodically sampled thereafter. The bandwidth calibration engine 106 is implemented within a digital control path 110 (shown, generally, as block 110) and utilizes the voltage and temperature measurements from TMON 122 and VMON 124 to determine calibration settings that compensate for PVT variations affecting the PLL bandwidth, as discussed herein.

Phase-frequency detector 112 receives and compares reference clock 126 and feedback clock 138 (or an optional divided feedback clock 140 produced by frequency divider 120) obtained from the feedback path, and determines control signals 130 at least partially based thereon. Feedback clock 138 is, or is indicative of, output clock 136 generated by voltage-controlled oscillator 118. Phase-frequency detector 112 outputs control signals 130, which are based on the phase or frequency difference between reference clock 126 and feedback clock 138, to a charge pump 114.

Charge pump 114 receives control signals 130 and in response to control signals 130 (and based on various operating parameters set by calibration control signals 142, discussed below) sources or sinks current into an analog loop filter 116 via charge pump output current Icp 132. The analog loop filter 116, in response to charge pump output current 132, produces a control voltage 134 that is provided to a voltage-controlled oscillator (VCO) 118.

Charge pump 114 also receives calibration control signals 142, which signals are distinct from phase-frequency detector 112 control outputs (control signals 130) that drive the charge pump 114 during closed-loop operation. Instead, calibration control signals 142 are used during a calibration phase to program operating parameters of charge pump 114 that determine the nominal total charge pump current of charge pump 114. For example, one of these signals may specify the number of active charge pump stages, another may set the scaling or per-unit current (often as an n-bit value), and a third signal may provide additional fine-tuning adjustments.

During closed-loop operation, the charge pump 114 responds dynamically to the UP and DOWN pulses of control signals 130 generated by phase-frequency detector 112. These pulses modulate the charge pump output current 132, causing the effective amount of charge transferred to or from the loop filter to vary in real time to reduce phase or frequency errors and to drive the PLL towards lock. Thus, while the calibration process sets the nominal total charge pump current (Icp_typ) as a parameter for stabilizing the PLL bandwidth, the net charge delivered by the charge pump 114 during closed-loop operation is dynamically adjusted as the PLL acquires and maintains lock.

As the voltage-controlled oscillator 118 adjusts its output in response to changes in control voltage 134, the frequency of its signal varies accordingly; this output frequency is delivered at the output clock 136, e.g., for subsequent processing or external use, without limitation. A portion of the VCO output is directed through a feedback path as feedback clock 138, which optionally includes a frequency divider 120, often referred to as a feedback divider, which generates a divided feedback clock 140, which is a lower-frequency version of feedback clock 138 that is supplied back to the phase-frequency detector 112. This closed-loop configuration enables phase-locked loop 104 to lock the VCO output frequency (frequency of output clock 136) to the frequency of reference clock 126 or an integer or fractional multiple versions thereof.

The bandwidth calibration engine 106, in conjunction with the digital control path 110, provides multiple digital control signals that configure and adjust the PLL. In one or more examples, an M-Bit control signal 152 (“/M” where “M” is an integer) sets the number of active charge pump stages within the charge pump 114, while an M-bit control signal 150 (“/N)” determines the unit charge pump current. These settings collectively define the total charge pump current of charge pump 114.

Additionally, digital control path 110 may generate a P-bit control signal 144 (“/P” also referred to herein as “coarse control 144” where “P” is an integer) used for coarse tuning of the VCO 118. In frequency calibration, discussed below, coarse control 144 is utilized to set the voltage-controlled oscillator 118 close to desired operating frequency so the Kvco measurement in the next operation is accurate. Also, these P-bit may, in one or more examples, include coarse frequency tuning bits and optionally fine frequency tuning bits.

Although system 100 operates in a closed-loop mode during standard operation, during calibration the digital control path 110 and calibration engine 106 switch the PLL into an open-loop mode to facilitate the measurement and characterization of the VCO gain (Kvco).

In one or more examples, in an open-loop measurement of Kvco, bandwidth calibration engine 106 directs the digital control path 110 to set the VCO 118 control voltage 134 to two distinct levels. More specifically, bandwidth calibration engine 106 disconnects the charge pump 114 from the loop filter to place the PLL 104 in an open-loop configuration via CP control for Kvco measurement 148 and controls the analog loop filter 116 directly via O-bit LF control (“/O” where “O” is an integer) for open-loop Kvco measurement 146 to set the control voltage 134 to the distinct levels generated from a built-in digital-to-analog converter (DAC) without limitation. For each of these levels, the frequency of the output clock 136—or more specifically, the frequency of the feedback clock 138/divided feedback clock 140—is measured. Dividing the change in frequency (Δf) by the change in control voltage (ΔVcontrol) yields measured Kvco. The bandwidth calibration engine 106 then compares this measured Kvco to a stored or predetermined target value (target Kvco) to determine a deviation, ΔKvco. The determined deviation, ΔKvco, is used to determine a charge pump current adjustment (ΔIcp); in some examples, if post-calibration supply voltage or temperature drift is not considered, ΔIcp may be determined directly based on ΔKvco, i.e., the difference between measured Kvco and Kvco_typ. In other examples where post-calibration VT drift is considered, ΔIcp may be determined based on a predetermined relationship that describes how a typical PLL bandwidth and/or a typical Kvco responds to changes in temperature, supply voltage, or both. In some examples, a simple inverse relationship between Kvco and Icp may be utilized. Additionally or alternatively, bandwidth calibration engine 106 may incorporate a more detailed characterization of the temperature and supply voltage dependencies of Kvco—potentially through polynomial approximations and scaling factors, e.g., measured via simulation/silicon characterization or production test, without limitation and stored in a lookup table (LUT) at bandwidth calibration engine 106 or digital control path 110—to determine an adjusted version of the charge pump current adjustment ΔIcp that accounts for anticipated VT drift.

As mentioned, above, the non-linear relationship used when accounting for post-calibration VT drift may be represented as a polynomial expression (e.g., the scaling factor may be a polynomial function). For example, the non-linear relationship may be approximated with a general Nth order polynomial. For example, a general 2nd order (N=2) polynomial of the form:

$$PLL BW ( Icp , Kvco ) = {a}_{2} \cdot {Icp}^{2} + {b}_{2} \cdot {Kvco}^{2} + {a}_{1} \cdot Icp + {b}_{1} \cdot Kvco + {c}_{1} \cdot Icp \cdot Kvco + {d}_{0}$$

Similarly for Temperature & Voltage dependencies for Kvco may be expressed in the form:

$$Kvco ( T ) = {m}_{2} \cdot {T}^{2} + {m}_{1} \cdot T + {m}_{0}$$

$$Kvco ( V ) = {n}_{2} \cdot {V}^{2} + {n}_{1} \cdot V + {n}_{0}$$

$$Kvco ( T , V ) = {m}_{2} \cdot {T}^{2} + {n}_{2} \cdot {V}^{2} + {m}_{1} \cdot T + {n}_{1} \cdot V + {o}_{1} \cdot T \cdot V + {p}_{0}$$

These coefficients can be measured in simulation/silicon characterization or production test and stored (e.g., in an LUT, without limitation). Stored coefficients to be used in the VT-aware flow at start-up.

Following the open-loop measurement of Kvco, bandwidth calibration engine 106 updates the M-Bit control signal 152 and/or M-bit control signal 150, thereby setting the total charge pump current Icp_typ deliverable as charge pump output current 132 by charge pump 114. These settings are established as one-time settings aimed at stabilizing the PLL bandwidth under varying operating conditions. Here, “one-time setting” means that the adjustments are static and made during a calibration process. The calibration process may be run multiple times if appropriate.

In one or more examples, target Kvco may be obtained any suitable way, as non-limiting examples, from a calibrated PLL or from a manufacturer of the PLL design that includes the VCO—e.g., the manufacturer may provide suggested target Kvco by doing simulation, silicon char or production test, without limitation.

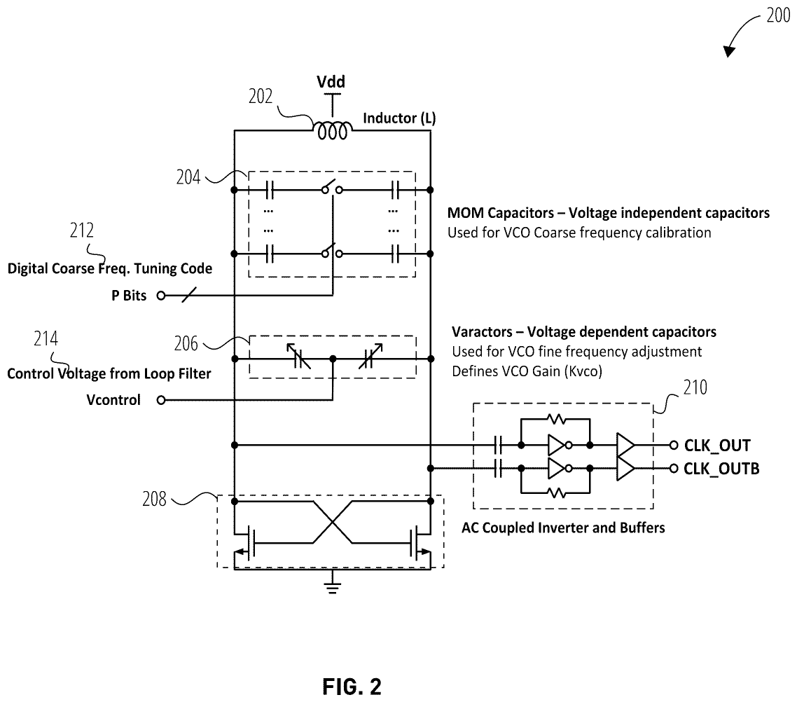

FIG. 2 is a schematic diagram depicting a circuit 200, which is an example of an LC-based voltage-controlled oscillator (LC VCO) that receives both coarse control (P-bits) and fine frequency tuning (via Vcontrol), in accordance with one or more examples.

At the upper portion of the figure, an inductor 202 is connected to a supply voltage (Vdd), forming part of the tank circuit that sets the resonant frequency of the VCO along with multiple capacitors. Circuit 208 are cross-coupled devices (e.g., an NMOS or CMOS inverter pair, without limitation) that provides gain or negative resistance into the tank so the LC-tank VCO can sustainably oscillate. The capacitors of capacitor bank 204 adjacent to inductor 202 (depicted as coupled in parallel to inductor 202) may be, as non-limiting examples, voltage-independent metal-oxide-metal (MOM) capacitors or metal-insulator-metal (MiM) capacitors, depicted at capacitor bank 204. In one or more examples, these MOM capacitors may be switched in or out of the circuit in discrete operations or acts under control of a digital coarse frequency tuning code 212 (a P-bit code), allowing large frequency adjustments to move the VCO output frequency close to the target operating frequency.

Below the coarse tuning elements, varactors 206 are shown. Varactors 206 are voltage-dependent capacitors that adjust their capacitance in response to a control voltage (Vcontrol) 214 provided from a loop filter (not illustrated in full detail in FIG. 2, but analog loop filter 116 of FIG. 1 is a non-limiting example). Because the varactors 206 vary in capacitance with changes in their applied voltage (here, changes in their applied voltage responsive to changes in Vcontrol 214), they enable fine frequency adjustments in the VCO, and their gain with respect to the control voltage—which is Kvco—directly influences the VCO's overall tuning sensitivity. The MOM capacitors at capacitor bank 204 and varactors 206 together provide a full range of VCO's frequency tuning capability, accommodating both coarse and fine adjustments as needed (e.g., depending on specific operating conditions, without limitation).

The control voltage Vcontrol 214 from the PLL's loop filter drives the varactors 206 to lock the VCO's output frequency to the phase and/or frequency of a reference clock or its integral or fractional multiple. By tuning the varactors 206, the circuit 200 can correct for phase or frequency errors detected elsewhere in the PLL. Once the tank circuit formed by the inductor 202 and the capacitive elements (capacitor bank 204, varactors 206) resonates at the desired frequency, one or more AC coupled inverter and buffers 210 produce differential, rail-to-rail, clock signals labeled CLK_OUT and CLK_OUTB. These buffers provide isolation between the resonant tank and the load, preserving the low phase noise characteristic of the VCO and minimizing the impact of downstream circuitry on the oscillator core.

In a contemplated operation, the VCO circuit 200 may utilize digitally controlled switches (such switches not depicted in FIG. 2) to select the number of MOM capacitors of capacitor bank 204 that are switched in or out in discrete operations or acts, establishing the coarse portion of the desired frequency range. The control voltage Vcontrol applied to the varactors 206 fine-tunes the final oscillation frequency.

The varactors 206 are at least partially responsible for determining the VCO gain (Kvco) by varying their capacitance in response to the control voltage (Vcontrol). Variations in the capacitance of varactors 206—induced by process, supply voltage, and temperature (PVT) fluctuations—result in corresponding deviations in Kvco, which can in turn affect the PLL's closed-loop bandwidth. Example compensation techniques discussed herein may be used to reduce such deviations. VCO frequency may be measured at two distinct Vcontrol levels to determine a measured Kvco value. The measured Kvco value may be compared to a predetermined value to determine a ΔKvco value, representing the deviation from a predetermined target value. This ΔKvco is then used to adjust the total charge pump current (Icp) as described with respect to FIG. 1, so that the product of Icp×Kvco remains substantially constant. In this manner, the digitally controlled adjustment of the charge pump output current Icp offsets (e.g., reduces, without limitation) the variation in Kvco caused by the varactors 206, thereby ensuring that the PLL maintains a stable bandwidth despite inherent PVT variations.

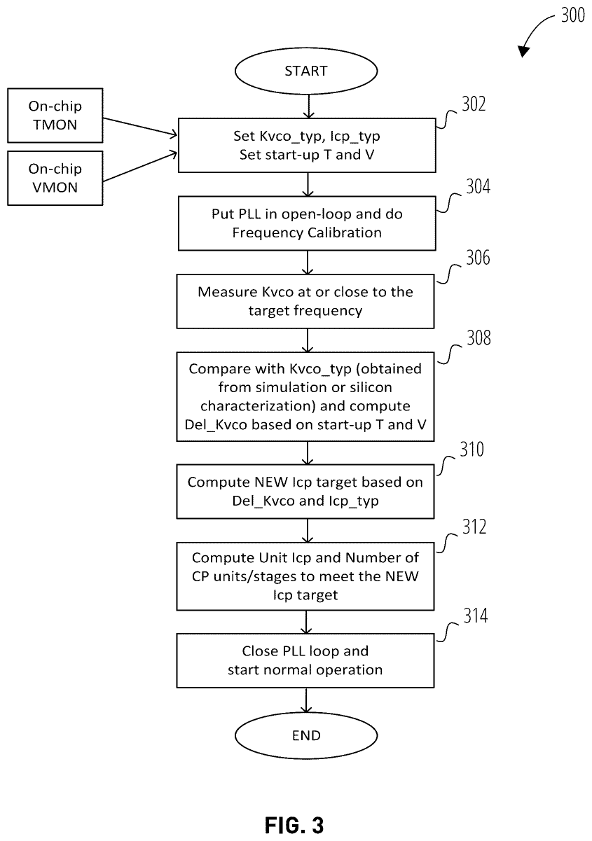

FIG. 3 is a flow diagram depicting a process 300 to calibrate a PLL to maintain a stable PLL bandwidth in view of potential PLL bandwidth variation due to variation in VCO gain Kvco, in accordance with one or more examples.

Although process 300 depicts a particular sequence of operations, the sequence may be altered without departing from the scope of the present disclosure. For example, some of the operations depicted may be performed in parallel or in a different sequence that does not materially affect the function of the process 300. In other examples, different components of an example device or system that implements the process 300 may perform functions at substantially the same time or in a specific sequence. Some or a totality of operations of process 300 may performed, as a non-limiting example, by bandwidth calibration engine 106, digital control path 110, or PLL system 100 more generally.

In one or more examples, process 300 may include initializing calibration parameters by loading a predetermined VCO gain target (Kvco_typ) and a nominal charge-pump current target (Icp_typ), and capturing the PLL's start-up temperature (T) and supply voltage (V) from on-chip monitors (TMON and VMON), at operation 302. The logic first retrieves the typical Kvco and Icp values—obtained, for example, from prior simulation or silicon characterization—and stores these as reference points. Simultaneously, the on-chip temperature sensor reports the die temperature, and the voltage monitor reports the supply-rail level at start-up. These environmental readings inform subsequent calibration operations by providing the baseline conditions under which the PLL will be configured in open-loop mode.

In one or more examples, process 300 may include placing a PLL into an open-loop mode to conduct a frequency calibration, at operation 304. In open-loop mode, the loop filter output and VCO control signals can be directly manipulated and measured without interference from the normal feedback mechanism. On-chip temperature and voltage monitors (TMON and VMON) provide real-time environmental data for reference, enabling accounting for changes in temperature or supply voltage.

In one or more examples, process 300 may include measuring the VCO gain (Kvco) by applying at least two distinct control voltages to the VCO and recording the corresponding output frequencies, at operation 306. By dividing the change in frequency (Δf) by the change in control voltage (ΔVcontrol), process 300 calculates the measured Kvco at or about the target frequency.

In one or more examples, process 300 may include comparing measured Kvco with a target Kvco value, at operation 308. In one or more examples, the target Kvco may be predetermined value for example, obtained from silicon characterization, simulation, or prior measurements, without limitation. The deviation, ΔKvco, is indicative of how much the actual VCO gain deviates from its expected value under current operating conditions.

In one or more examples, process 300 may include determining a new target for the total charge pump current (Icp) at least partially based on ΔKvco, at operation 310. In one or more examples, the PLL bandwidth is approximated as proportional to the product of Icp×Kvco; therefore, if Kvco is higher than nominal (as represented by the target Kvco value), Icp may be reduced to keep the bandwidth near its design target, and vice versa. In one or more examples, process 300 may also factor in TMON and VMON readings to predict future VT drift, using polynomial or lookup-table (LUT) corrections if needed.

In one or more examples, process 300 may include determining how the charge pump's digital control signals—such as an m-bit setting for the number of active pump stages and an n-bit setting for the per-unit current-should be set or changed to realize the new target total charge pump current Icp, at operation 312.

In one or more examples, with these calibrated settings in place, the process 300 may include closing the PLL loop and commence normal operation, at operation 314. As the system transitions into closed-loop mode, the calibrated charge pump current helps compensate for Kvco variation and maintain a stable PLL bandwidth across process, supply voltage, and temperature (PVT) variation.

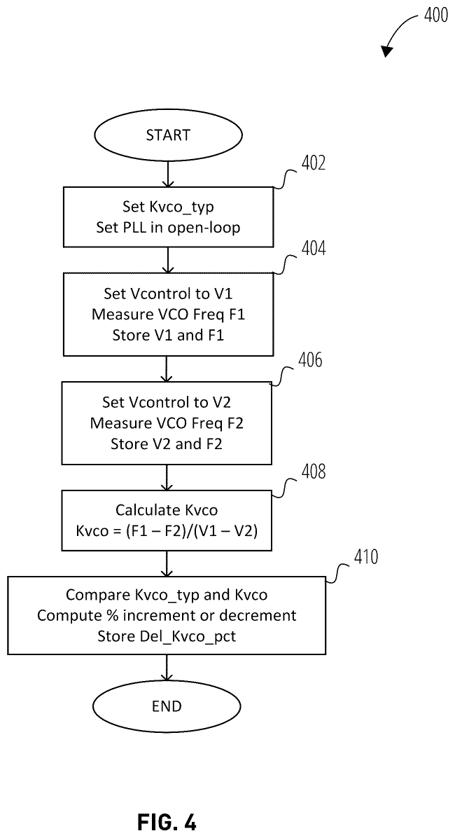

FIG. 4 is a flow diagram depicting a process 400 to measure VCO gain (Kvco) in an open-loop mode, in accordance with one or more examples. Process 400 measures Kvco without accounting for post-calibration supply voltage or temperature drift. It is assumed that at the start of process 400 the system has performed an open-loop VCO frequency tuning calibration (e.g., as discussed above with respect to process 300 of FIG. 3, without limitation) so that the Kvco measurement in process 400 is substantially accurate.

Although process 400 depicts a particular sequence of operations, the sequence may be altered without departing from the scope of the present disclosure. For example, some of the operations depicted may be performed in parallel or in a different sequence that does not materially affect the function of the process 400. In other examples, different components of an example device or system that implements the process 400 may perform functions at substantially the same time or in a specific sequence. Some or a totality of operations of process 400 may performed, as a non-limiting example, by bandwidth calibration engine 106, digital control path 110, or PLL system 100 more generally.

In one or more examples, process 400 may include identifying or setting a target Kvco (Kvco_typ) and placing the PLL into open-loop operation, at operation 402. Target Kvco may be obtained, as non-limiting examples, from prior silicon characterization, simulation, or documentation.

In one or more examples, process 400 may include obtaining a first frequency measurement, at operation 404. Obtaining the first frequency measurement may include setting the VCO's control voltage (Vcontrol) to a first level V1, measuring the VCO output frequency F1 (produced in response to V1), and storing this frequency measurement F1 as the first frequency measurement.

In one or more examples, process 400 may include obtaining a second frequency measurement, at operation 406. Obtaining the second frequency measurement may include setting the VCO's control voltage to a second level, V2 (the second level is different than the first level), measuring the VCO output frequency F2 (produced in response to V2), and storing the frequency measurement F2 as the second frequency measurement.

In one or more examples, process 400 may include determining Kvco according to the formula:

$${K}_{vco} = \frac{F 1 - F 2}{V 1 - V 2} ,$$

at operation 408. The formula represents how much the output frequency changes for a given change in the VCO's control voltage.

In one or more examples, process 400 may include comparing measured Kvco with a target Kvco to determine the deviation Del_Kvco_pct, at operation 410.

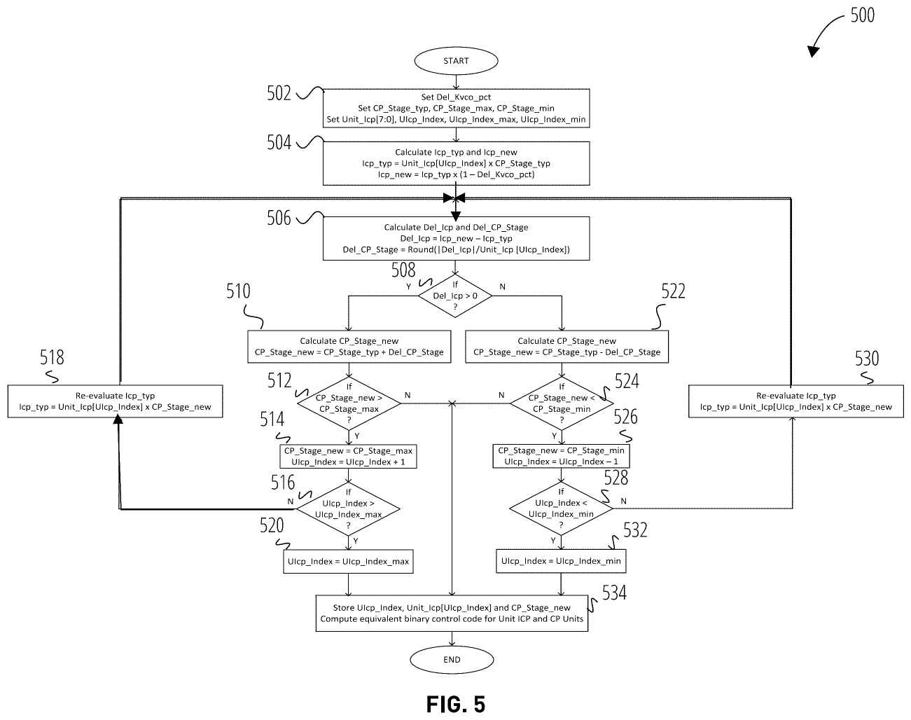

FIG. 5 is a flow diagram depicting a process 500 to determine the number of active charge pump (CP) stages and the unit charge pump current (Unit_Icp) in a phase-locked loop (PLL), in accordance with one or more examples.

Although the example process 500 depicts a particular sequence of operations, the sequence may be altered without departing from the scope of the present disclosure. For example, some of the operations depicted may be performed in parallel or in a different sequence that does not materially affect the function of the process 500. In other examples, different components of an example device or system that implements the process 500 may perform functions at substantially the same time or in a specific sequence. Some or a totality of operations of process 500 may performed, as a non-limiting example, by bandwidth calibration engine 106, digital control path 110, or PLL system 100 more generally.

At the start of process 500, it is assumed that the system has already measured or otherwise obtained the VCO gain deviation Del_Kvco_pct (e.g., by measuring Kvco at two control voltage settings as discussed above with respect to process 400 of FIG. 4, without limitation).

In one or more examples, the process 500 may include, at operation 502, initializing parameters. The system loads (i) the measured or previously determined VCO gain deviation, denoted as Del_Kvco_pct (a percentage expressing how much Kvco differs from its target), (ii) the typical or default number of active charge pump stages (CP_Stage_typ) that would be used under nominal conditions, (iii) the current index for per-unit charge pump current (UIcp_Index), and (iv) boundary values that define the minimum and maximum allowable number of active charge pump stages (CP_Stage_min, CP_Stage_max). These initializations set the stage for subsequent calculations by providing the data needed to derive an updated total Icp that offsets the VCO gain deviation.

In one or more examples, the process 500 may include, at operation 504, calculating two intermediate values for the charge pump current. The parameter Icp_typ is determined by multiplying the per-unit charge pump current-retrieved from a lookup table at the index UIcp_index—by the typical number of stages, CP_Stage_typ. This yields the nominal or baseline current (a target charge pump current) that would be used if Kvco precisely matched its design target. Next, an updated current value (Icp_new) is determined by scaling Icp_typ according to (1−Del_Kvco_pct). Thus, if Del_Kvco_pct is positive (indicating Kvco is higher than nominal), Icp_new is reduced proportionally, and if Del_Kvco_pct is negative, Icp_new could increase. The parameter, Icp_new, which is the interim target total charge pump current that will be used to guide how many CP stages are activated and how much current each provides. The process will use Icp_new in the next operation to calculate final indices.

In one or more examples, the process 500 may include, at operation 506, deriving proposed new settings: CP_Stage_new (the number of charge pump stages to enable) and UIcp_Index_new (the index selecting the per-unit charge pump current). By referencing Icp_new, the system determines how to distribute that current across discrete CP stages. If, for example, Icp_new is lower than Icp_typ, the process may reduce the number of active CP stages or shift the unit charge pump current index downward. Conversely, if Icp_new is higher, the process adjusts the values upward. In this context, “new” emphasizes that these determined values may differ from the nominal or default settings of CP_Stage_typ and UIcp_Index.

In one or more examples, the process 500 may include, at operation 508, determining whether Del_Icp is greater than zero. The choice of zero as a decision threshold reflects whether the new current (Icp_new) is higher or lower than the baseline (Icp_typ):
If Del_Icp>0, The system increases the total CP current above the baseline to compensate for a Kvco that is lower than nominal. This leads to the path containing operations 510, 512, 514, 516, 518, and 520.
If Del_Icp≤0, The system decreases or maintains the total CP current relative to Icp_typ, indicating a Kvco that is higher or near nominal. In that case, the flow proceeds to operations 522, 524, 526, 528, 530, and 532.

First Path (If Del_Icp>0), which includes operations 510, 512, 514, 516, 518, 520:

Collectively, these operations define a controlled, stepwise approach for increasing the charge pump's total current in response to a lower-than-nominal VCO gain. In one or more examples, when Del_Icp is greater than zero, the process first increments the number of charge pump stages (CP_Stage_new) at operation 510, thereby raising the baseline current. At operation 514, process 500 adjusts the per-unit current by incrementing the UIcp_Index to provide additional current from each active CP stage. The system verifies at operation 518 that the recalculated nominal current (Icp_typ) now more closely approaches the higher total target current (Icp_new). This controlled, stepwise approach ensures that the increased total current remains within hardware limits, so that the PLL's closed-loop bandwidth is stabilized despite the lower-than-nominal VCO gain.

In one or more examples, the process 500 may include, at operation 510, determining CP_{Stage}_{_{new}} by adding a derived offset (Del_CP_Stage) to the typical number of CP stages (CP_{Stage}_{_{typ}}), where the derived offset Del_CP_Stage is a function of Del_Icp. Since Del_Icp>0 indicates that the PLL requires more total current to compensate for a lower-than-nominal VCO gain, so process 500 increases the nominal number of charge pump stages.

In one or more examples, the process 500 may include, at operation 512, determining whether CP_{Stage}_{_{new}} (as updated at operation 510) exceeds hardware or design limits. In one or more examples, process 500 may determine whether CP_Stage_new is greater than CP_{Stage}_{ₘₐₓ} to determine if CP_stage_new exceeds hardware or design limits.

If process 500 determines that CP_Stage_new>CP_Stage_max, then in one or more examples, process 500 may include, at operation 514, clamping CP_Stage_new to CP_Stage_max. Clamping CP_Stage_new to CP_Stage_max ensures that process 500 does not attempt to enable (via CP_Stage_max) more charge pump stages than physically available (a hardware limit) or permitted by design constraints (a design limit).

If, at operation 512, process 500 determines that CP_{Stage}_{_{new}}>CP_{Stage}_{ₘₐₓ} hen in one or more examples, process 500 may also include, at operation 514, incrementing by one the per-unit current index, UIcp_{Index}. If enabling additional CP stages alone does not achieve the newly determined target charge pump current, process 500 increases the amount of current contributed by each active charge pump stage. By adding one increment to UIcp_{Index}, each charge pump stage is instructed to deliver more current.

If, at operation 512, process 500 determines that CP_Stage_new is less than CP_Stage_max, in one or more examples, process 500 may progress directly to operation 534 without further adjusting CP_Stage_new or UIcp_Index.

In one or more examples, the process 500 may include, at operation 516, determining whether UIcp_{Index} (as updated in operation 514) remains within hardware or design limits. In one or more examples, process 500 determines whether UIcp_Index is greater than UIcp_Index_max to determine whether UIcp_Index is within hardware or design limits.

In one or more examples, if, at operation 516, process 500 determines that UIcp_{Index} is greater than UIcp_{Index}_{ₘₐₓ} process 500 may include, at operation 520, clamping UIcp_Index to UIcp_{Index}_{ₘₐₓ} d progressing directly to operation 534. Clamping UIcp_Index to UIcp_Index_max prevents the per-unit charge pump current from exceeding a hardware specification (a hardware limit) or design constraint (a design limit).

In one or more examples, If process 500 determines that UIcp_{Index} is not greater than (less than or equal to) UIcp_{Index}_{ₘₐₓ} process 500 may include at operation 518, re-evaluating the nominal current Icp_typ (or some interim parameter) or recalculating the new total current from the updated parameters. In one or more examples, process 500 determines the re-evaluated Icp_{typ} as “Unit_Icp”[UIcp_Index]×CP_Stage_new. Upon updating Icp_typ, process 500 progresses to operation 506 and may evaluate CP_Stage_new and UIcp_index with the updated Icp_typ as discussed above.

If the difference between newly combined settings (CP_Stage_new and UIcp_Index) and compensated current requirements derived from Del_Icp remains significant, the loop may continue adjusting these parameters. If the difference is within a tolerance, the path converges and eventually proceeds to store the final values at operation 534. This ensures that by the end of the process, the PLL has a suitably higher total charge pump current to offset the measured deficit in VCO gain and maintain its target bandwidth.

Second Path (If Del_Icp≤0), which includes operations 522, 524, 526, 528, 530, 532:

Collectively, these operations define a controlled, stepwise approach for reducing the charge pump's total current in response to a higher-than-nominal VCO gain. By optionally adjusting CP_{Stage}_{_{new}} at operation 522 to reduce the number of active charge pumps and/or decrementing UIcp_{Index} at operation 526 to provide less current from each active CP stage, process 500 may precisely dial down the current while ensuring neither parameter drops below its respective hardware minimum. The re-evaluation of Icp_{typ} at operation 530 confirms how close the system is to achieving the target, thus preserving a stable closed-loop bandwidth.

In one or more examples, the process 500 may include, at operation 522, determining a new, smaller number of charge pump stages (CP_{Stage}_{_{new}}) by subtracting a derived offset (Del_{CP}_{_{Stage}}) from the typical number of CP stages (CP_{Stage}_{_{typ}}). Because a negative or zero Del_Icp implies the total current should be decreased from, or held the same as, the baseline, process 500 reduces the count of active CP stages (CP_Stage_new) accordingly. The derived offset Del_CP_Stage provides an initial value for the number of CP stages to disable (if any) to align the total charge pump current with the measured VCO gain deviation.

In one or more examples, the process 500 may include, at operation 524, determining whether CP_{Stage}_{_{new}} is less than a hardware or design limit (e.g., a minimum allowable number of CP stages based on hardware specification or design constraints, without limitation), CP_{Stage}_{ₘᵢₙ} f, at operation 524, process 500 determines that CP_Stage_new is not less than (i.e., is greater or equal to) CP_Stage_min, then process 500 may progress directly to operation 534 without further adjustment of CP_stage_new or UIcp_index.

If, at operation 524, process 500 determines that CP_Stage_new is less than CP_Stage_min, in one or more examples, process 500 may include, at operation 526, clamping CP_Stage_new to CP_{Stage}_{ₘᵢₙ} lamping CP_Stage_new to CP_Stage_min ensures the system cannot disable more charge pump stages than allowed.

If, at operation 524, process 500 determines that CP_{Stage}_{_{new}} is less than CP_Stage_min, in one or more examples, process 500 may also include, at operation 526, decrementing the per-unit charge pump current UIcp_{Index}. If lowering the number of CP stages, CP_Stage_new, alone does not achieve the newly determined target charge pump current, process 500 may decrease the amount of current contributed by each active charge pump stage and thereby reduce the total charge pump current to attempt to bring it closer to the determined target charge pump current.

In one or more examples, the process 500 may include, at operation 528, determining whether UIcp_{Index} is less than UIcp_{Index}_{ₘᵢₙ} f it is, process 500 cannot decrement any further without violating hardware or performance limits.

If, at operation 528, process 500 determines that UIcp_{Index} is less than UIcp_{Index}_{ₘᵢₙ} process 500 may include, at operation 532, clamping UIcp_{Index} to UIcp_{Index}_{ₘᵢₙ} ensuring the per-unit current does not go below the allowable limit.

If, at operation 528, process 500, determines that UIcp_Index is not less (i.e., greater than or equal to) UIcp_Index_min, in one or more examples, process 500 may include, at operation 530, re-evaluating Icp_{typ} (or another interim variable) to determine a new typical charge pump current. Specifically, Icp_{typ} may be re-determined as the product of a chosen per-unit current Unit_Icp derived from UIcp_{Index} (Unit_Icp [UIcp_Index]), and the newly determined CP_{Stage}_{_{new}}. Upon determining the re-evaluated Icp_typ at operation 530, process 500 progresses to operation 506 to use the newly determined Icp_typ to evaluate CP_Stage_new and UIcp_Index_min as discussed above.

If the difference between newly combined settings (CP_Stage_new and UIcp_Index) and compensated current requirements derived from Del_Icp remains significant, the loop may continue adjusting these parameters. If the difference is within a tolerance, the path converges and eventually proceeds to store the final values at operation 534. This ensures that by the end of the process 500 (coming into operation 534), the PLL has a suitably adjusted total charge pump current to offset the measured deviation in VCO gain and maintain the target PLL bandwidth.

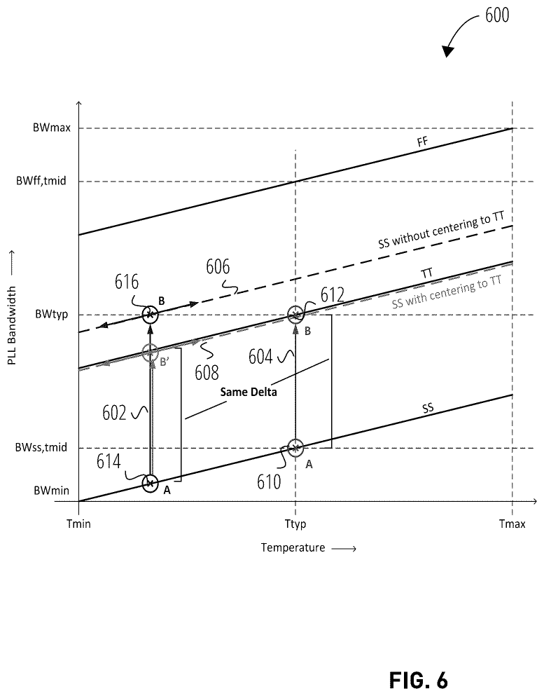

FIG. 6 is a chart depicting a relationship between PLL bandwidth and temperature. The solid black lines labeled FF, TT and SS are the curves that represents the typical relationship between the PLL bandwidth and temperature when the transistors used to implement the PLL circuit is fabricated in a fast-fast, typical-typical, and slow-slow process corner, respectively.

Note, black lines FF, TT and SS have respective slopes, so they vary with temperature. Respective slopes may be used to account for temperature drift. To account for VT drift in PLL bandwidth compensation, the plots from various process corners are centered across the typical curve. For example:

Arrow 604 is an example where there is no temperature drift, PLL bandwidth variation is only due to process change from TT to SS. Point 610 (“A”) (on plot SS) is the start-up point where Kvco is measured and Del_Kvco is calculated (shown as the delta in PLL bandwidth). The location of point 610 is shifted to the location of shifted point 612 (“B”) (on plot TT) by adjusting the Icp thereby compensating for the offset in bandwidth.

Arrow 602 and line 606 are examples where the PLL is in SS process corner and the start-up temperature is below typical temperature at point 614 (“A”). Without T-aware algorithm the Del_Kvco calculated would be more than required and this would shift the location of point 614 to the location of shifted point 616. This would reduce the offset in the PLL bandwidth, but it can be optimized further to reduce the spread from the desired typical plot.

Green arrow and line 608 is an example where T-aware algorithm scales the measured Kvco, based on start-up temperature at point 614, such that the determined Del_Kvco and new Icp target centers the PLL bandwidth across the TT plot.

The algorithm works in a similar way when the process corner is FF, or the startup temperature is higher than the typical temperature. Similar logic is applied to compensate PLL bandwidth variation due to supply voltage drift, V-drift. The objective is to calculate Del_Kvco based on start-up temperature and voltage and center the PLL bandwidth plot across typical.

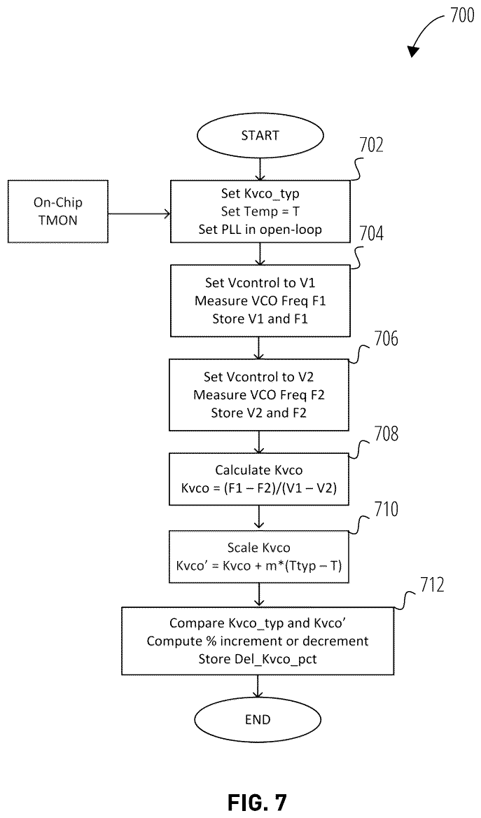

FIG. 7 is a flow diagram depicting a process 700 to measure VCO gain (Kvco) and apply a temperature-based scaling to measured Kvco to account for T-drift, in accordance with one or more examples. It is assumed that at the start of process 700 the system has performed an open-loop VCO frequency tuning calibration (as discussed above with respect to process 300 of FIG. 3, without limitation) so that the Kvco measurement in process 700 is more or less accurate.

Although the example process 700 depicts a particular sequence of operations, the sequence may be altered without departing from the scope of the present disclosure. For example, some of the operations depicted may be performed in parallel or in a different sequence that does not materially affect the function of the process 700. In other examples, different components of an example device or system that implements the process 700 may perform functions at substantially the same time or in a specific sequence. Some or a totality of operations of process 700 may performed, as a non-limiting example, by bandwidth calibration engine 106, digital control path 110, or PLL system 100 more generally.

In one or more examples, the process 700 may include, at operation 702, reading a temperature value T from the on-chip temperature monitor (TMON). This temperature reading may be performed at startup or at any time the system detects a significant temperature change. Process 700 sets an internal reference, Temp=T, to reflect the current measurement. The PLL is then placed into an open-loop calibration mode, allowing direct measurement of the VCO's frequency response without interference from the normal feedback mechanism.

In one or more examples, the process 700 may include, at operation 704, applying a first control voltage V1 to the VCO and measuring the resulting output frequency F1. This first measurement is stored for later use. Subsequently, the control voltage is changed to a second value V2, and a second frequency measurement F2 is taken and stored. Collectively, (V1, F1) and (V2, F2) represent two operating points on the VCO's voltage-to-frequency characteristic at the currently measured temperature T.

In one or more examples, the process 700 may include, at operation 706, calculating the raw Kvco by using the frequency differences and the corresponding voltage differences. Specifically, Kvco is determined as:

$${K}_{vco} = \frac{F 1 - F 2}{V 1 - V 2}$$

This calculation reflects how sensitive the VCO output frequency is to changes in the control voltage, which is the definition of the VCO gain.

In one or more examples, the process 700 may include, at operation 708, applying a temperature-based scaling or transformation to the measured Kvco. Because the temperature may differ from a nominal reference temperature (Ttyp), the system can account for how the VCO gain changes with temperature by using a known or estimated linear (or polynomial) relationship. In one approach, the process 700, at operation 710, determines a translated (e.g., scaled, without limitation) gain, K′_{vco}, using the expression:

$${K}_{vco}^{′} = {K}_{vco} + m \times ( Ttyp - T )$$

Where m is a coefficient of the linear relationship between Kvco and temperature determined from prior simulation, silicon characterization, or both, as non-limiting examples. This operation incorporates the effect of T-drift on the raw measured gain.

In one or more examples, the process 700 may include referencing the known typical temperature T_typ to ascertain how far the actual temperature T deviates. The system may use either a stored LUT (lookup table) or a linear or a polynomial approximation to predict how the VCO gain shifts. Thus, if T is higher than T_typ the VCO gain may be translated (e.g., scaled, without limitation) accordingly; if T is lower than T_typ, the system may apply a different offset or slope.

In one or more examples, the process 700 may include, at operation 712, comparing the translated Kvco value (K′_{vco}) with a nominal or typical Kvco (Kvco_typ) and deriving a difference expressed as a percentage increment or decrement. This difference, often termed Del_Kvco_pct, indicates how much the actual (temperature-adjusted) VCO gain varies from the nominal design assumption under current temperature conditions. Storing Del_Kvco_pct (or an equivalent representation) concludes the measurement procedure. The PLL (or an associated calibration engine) may then utilize Del_Kvco_pct to adjust the charge pump current (Icp) or other loop parameters, thus compensating for T-drift and stabilizing the PLL bandwidth in closed-loop operation.

Throughout process 700, the open-loop calibration and the temperature measurement ensure that the system obtains a direct assessment of Kvco at the temperature T provided by TMON. By applying a temperature-based scaling operation, the process 700 recognizes that Kvco often exhibits a known functional dependence on T, and corrects or normalizes the raw measurement accordingly. Once the system has established an accurate representation of how the VCO gain shifts with temperature, it can proceed to update the PLL's loop parameters—particularly the total charge pump current (Icp)—to compensate for VCO gain variations. This approach limits bandwidth drift due to post-calibration temperature changes, thereby allowing the PLL to maintain stable performance across a broad range of operating conditions.

In one or more examples, an alternate approach to computing the temperature-compensated VCO gain deviation may include scaling the predetermined target VCO gain (Kvco_typ), rather than scaling the measured Kvco. In such implementations, the system may determine a temperature-adjusted target gain, denoted Kvco_typ′, using the expression:

$${Kvco\_typ}^{′} = Kvco\_typ + m \times ( T - Ttyp )$$

where T is the current temperature measured by the on-chip temperature monitor (TMON), Ttyp is a nominal or reference temperature, and m is a temperature-dependent coefficient derived from simulation, silicon characterization, or production test. The system may then determine the deviation of Kvco from its temperature-adjusted target by subtracting Kvco_typ′ from the measured Kvco value. This approach yields the same Kvco deviation (e.g., Del_Kvco or Del_Kvco_pct) as the approach that scales the measured Kvco directly, but may be preferred in some implementations based on control architecture, computational efficiency, or available data structures. The resulting deviation may be used in the same manner as described above to adjust PLL operating parameters, such as charge pump current, and thereby compensate for temperature-induced variation in Kvco.

Those having ordinary skill in the art will appreciate that the linear and higher-order polynomial approximation techniques described above for compensating VCO gain variation (Kvco) due to temperature drift (T drift) can be applied in an entirely analogous manner to compensate for VCO gain variation caused by supply-voltage drift (V drift). In such implementations, the independent variable T reported by the on-chip temperature sensor (TMON) is simply replaced by the supply-voltage variable V from the on-chip supply voltage monitor (VMON), and the temperature-dependent coefficients (e.g., m₁, m₂, without limitation) are replaced by voltage-dependent coefficients (e.g., n₁, n₂, without limitation) obtained from simulation, silicon characterization, or production test. Thus, the same look-up-table framework, piecewise linear segments, or second-order polynomial functions may be used to model Kvco (V) over a specified supply voltage range, with those coefficients stored and then retrieved during the open-loop calibration sequence. Accordingly, a person of ordinary skill in the art will recognize that the operations of scaling a measured Kvco according to m×(Ttyp−T) can be directly mirrored by scaling according to n×(Vtyp−V), and by routine substitution the described calibration process from temperature drift may be extended to voltage drift.

Further, in one or more examples, the calibration logic may perform both the temperature-based and voltage-based compensation processes in tandem. That is, the same polynomial or piecewise-linear approximation framework applied to correct Kvco(T) may be executed in parallel with an analogous compensation for Kvco(V), such that the measured VCO gain is first adjusted for temperature drift and then further adjusted (or vice versa) for supply-voltage drift (or both adjustments may be applied in a single combined update). By combining both compensation paths, the logic circuit can maintain a stable PLL bandwidth in the presence of simultaneous variations in temperature and supply voltage.

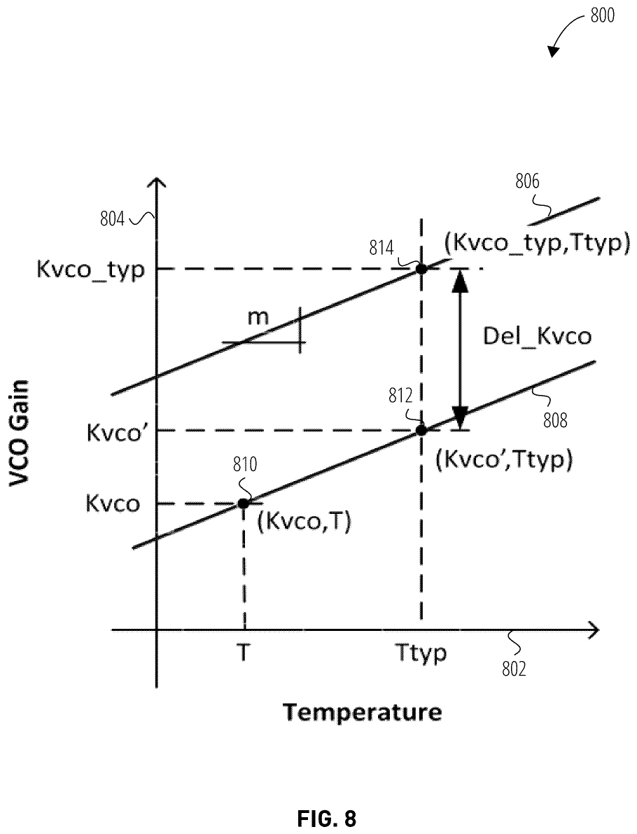

FIG. 8 is a conceptual diagram depicting a plot graph 800 of VCO gain (Kvco) versus temperature and shows how the measured Kvco at a particular temperature (T) can be translated or compared to a nominal Kvco_typ at a typical temperature (Ttyp). The figure generally has a horizontal axis 802 representing temperature and a vertical axis 804 representing Kvco. The figure shows two lines, line 806 and line 808, respectively representing a linear approximation of Kvco's dependence on temperature for potentially different scenarios or process corners. For instance, line 806 with slope “m” may depict the nominal or “typical” process behavior, while line 808 may correspond to a measured or translated (e.g., scaled, without limitation) behavior under certain conditions, as a non-limiting example, a different process corner. Visually and/or mathematically comparing line 806 and line 808 shows how measured Kvco might deviate from a nominal or typical scenario.

Point 810 is at the intersection of the measured Kvco value at the actual temperature T of the device, depicted on the line 808. Point 812 on line 808 indicates the translated VCO gain (Kvco′) adjusted to the typical reference temperature Ttyp. Point 814 on line 806 denotes the typical reference temperature (Ttyp) at which Kvco_typ is defined.

The vertical separation between the nominal gain at Ttyp (point 812 at 814) and the measured gain at temperature T (point 810) quantifies Del_Kvco, the extent of VCO gain drift due to a temperature deviation from Ttyp. This value is then used by the calibration circuitry to adjust the total charge pump current (Icp) and other PLL parameters, ensuring that despite variations in Kvco across different temperatures, the PLL's closed-loop bandwidth remains stable.

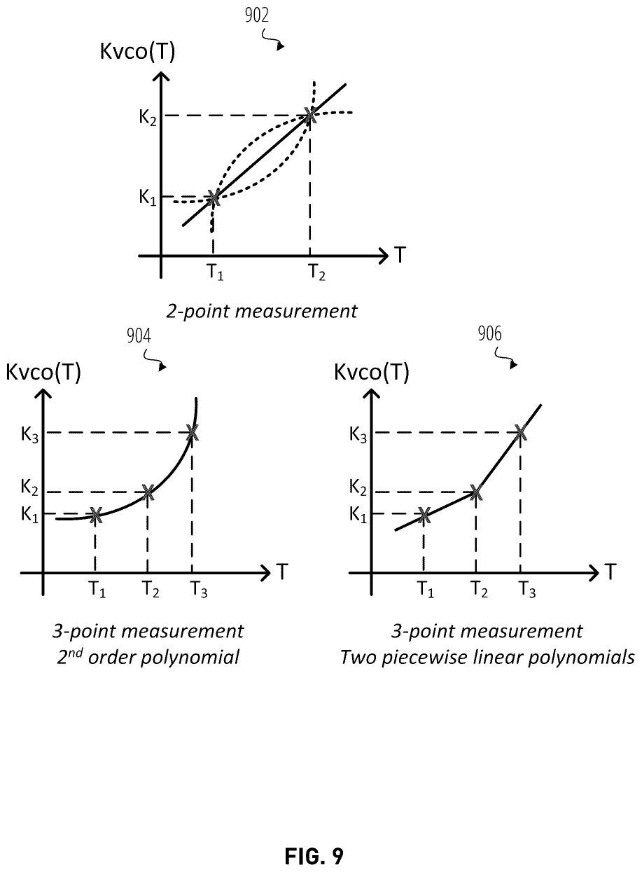

FIG. 9 depicts three conceptual graphs illustrating different methods of approximating a non-linear relationship between VCO gain (Kvco) and an independent variable, such as temperature or supply voltage, in accordance with one or more examples. These methods enable the system to account for higher-order effects when measuring and compensating Kvco variations in a phase-locked loop (PLL). Each sub-graph in FIG. 9 shows measured points (marked with red “X” symbols) at specific values of the independent variable (for instance, temperatures T₁, T₂, and possibly T₃). The resulting curves demonstrate different polynomial or piecewise linear fits to these measured data points.

2-Point Measurement (graph 902) In one or more examples, the system performs a measurement of Kvco at two distinct values of the independent variable (for example, temperature T₁ and T₂). These points are labeled K₁ at T₁ and K₂ at T₂. A straight line, shown as a dashed or solid curve passing through both red “X” symbols, approximates how Kvco changes over the entire range from T₁ to T₂. Because only two points are measured, this linear approximation is relatively simple and fast to determine, but it may be less accurate if the true relationship is significantly non-linear.

3-Point Measurement with a 2nd Order Polynomial (graph 904) In one or more examples, the system collects Kvco data at three different values of the independent variable. These three points (K₁, K₂, K₃) enable a 2nd order polynomial fit, depicted as the smooth, curved line passing through all three red “X” symbols. By considering three measurements instead of two, the system can capture curvature in the data, yielding a more accurate approximation of Kvco's non-linear behavior. Although more precise, this approach typically involves more computation or hardware resources to store the polynomial coefficients.

3-Point Measurement with a Two Piecewise Linear Approximation (plot graph 906) In one or more examples, rather than fitting a single 2nd order polynomial curve, the system connects the measured points with two linear segments—one between T₁ and T₂, another between T₂ and T₃. This “two piecewise linear” approach is less complex than solving for polynomial coefficients but more accurate than a single straight line over the entire range. By selecting the measured points (red “X” symbols) judiciously, the system can approximate modest non-linearities without resorting to higher-order polynomial fits.

Whether the system employs the 2-point measurement (graph 902), the 3-point 2nd order polynomial (graph 904), or the 3-point piecewise linear approach (graph 906), the primary goal is to obtain a function that accurately maps how Kvco shifts with changes in the independent variable (e.g., temperature). The resulting function or piecewise approximation may be stored in a lookup table (LUT) or coded as polynomial coefficients within the PLL's calibration engine. In operation, once Kvco is measured (or predicted) at a new condition, the PLL firmware or hardware uses these approximations to determine the charge pump current (Icp) or other loop parameters necessary to maintain the PLL's closed-loop bandwidth.

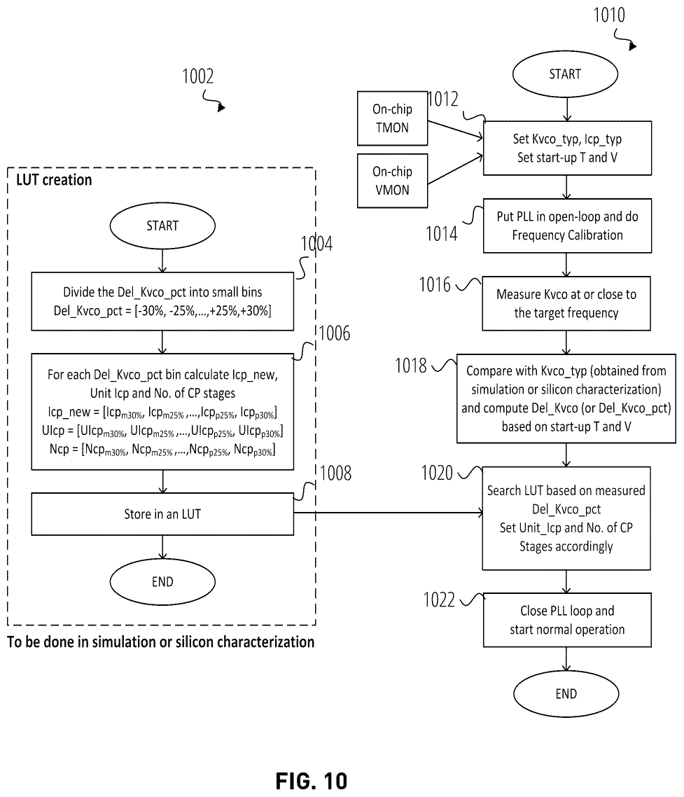

FIG. 10 shows two related flow diagrams-process 1002 on the left, which depicts creating a lookup table (LUT) for charge pump current (Icp) calibration, and process 1010 on the right, which depicts using the LUT at runtime to set the PLL's bandwidth parameters, respectively in accordance with one or more examples.

Although the example process 1002 and process 1010 respectively depict a particular sequence of operations, the sequence may be altered without departing from the scope of the present disclosure. For example, some of the operations depicted may be performed in parallel or in a different sequence that does not materially affect the function of the process 1002 and process 1010. In other examples, different components of an example device or system that implements the process 1002 and process 1010 may perform functions at substantially the same time or in a specific sequence. Some or a totality of operations of process 1002 and/or process 1010 may performed, as a non-limiting example, by bandwidth calibration engine 106, digital control path 110, or PLL system 100 more generally.

In one or more examples, process 1002 may include, at operation 1004, dividing the overall range into smaller bins (for instance, increments of 5%), ensuring each bin covers a specific subset of potential Kvco deviations.

In one or more examples, process 1002 may include, at operation 1006, identifying, for each Del_Kvco_pct bin, an appropriate total charge pump current (Icp_new), a per-unit current index (UIcp), and a number of active charge pump stages (Ncp). These values are derived using simulation or silicon characterization data that correlate Kvco deviations with adjustments in the charge pump current that will maintain the PLL's bandwidth near its design target. For instance, if Del_Kvco_pct=−25%, the process might determine a higher Icp_new or more active CP stages, whereas a Del_Kvco_pct=+30% may require the opposite. This ensures that each bin reflects practical hardware settings that compensate for the measured Kvco shift.

In one or more examples, process 1002 may include, at operation 1008, storing the determined calibration data in a lookup table (LUT). Each bin's entry associates a Del_Kvco_pct range with the corresponding Icp_new, UIcp, and Ncp values, allowing the system to quickly retrieve these settings whenever the measured Kvco deviation falls within that bin. This completes the LUT creation; thereafter, a separate calibration flow (such as process 1010) may reference the LUT at runtime or startup to select the proper charge pump configuration, obviating the need for repeated, real-time calculation of current parameters.

Turning to process 1010, in one or more examples, process 1010, at operation 1012, may include initializing the calibration by capturing both reference values, such as nominal VCO gain (Kvco_typ) and nominal charge pump current (Icp_typ) and environmental conditions prior to any real-time measurement. Specifically, on-chip temperature (TMON) and voltage (VMON) sensors are read to obtain the PLL's instantaneous die temperature (T) and supply voltage (V). Once Kvco_typ and Icp_typ have been determined, process 1010 advances to operation 1014 to begin an open-loop frequency calibration using these startup reference values.

In one or more examples, process 1010, at operation 1014, may include placing the phase-locked loop (PLL) into an open-loop condition to perform a frequency calibration. During this phase, on-chip monitors such as temperature (TMON) and voltage (VMON) may be optionally sampled to further refine the measurement conditions. With the feedback loop of the PLL intentionally disabled, the process can directly measure the VCO's frequency under controlled input voltages.

In one or more examples, process 1010, at operation 1016, may include measuring the VCO gain (Kvco) by applying at least two distinct control voltages and recording the corresponding output frequencies. By dividing the change in frequency by the change in control voltage, the system obtains a Kvco value at or around the target frequency. The process may also retrieve a nominal or simulated Kvco (Kvco_typ) from prior characterization data and determine the difference or ratio between the measured Kvco and Kvco_typ, yielding a Del_Kvco or Del_Kvco_pct term that quantifies the current VCO gain deviation.

In one or more examples, process 1010, at operation 1018, may include referencing the measured temperature (T) or voltage (V) to apply any necessary polynomial or LUT-based scaling factor, ensuring that Del_Kvco_pct accurately reflects the VCO gain shift under the present process, supply voltage, and temperature (PVT) conditions. Once the system determines a final Del_Kvco_pct, it proceeds to operation 1020.

In one or more examples, process 1010, at operation 1020, may include searching the LUT created by process 1002 for the appropriate bin corresponding to the current Del_Kvco_pct. For instance, if the measured deviation is within a specific bracket (for example, −10% to −5%), the system accesses the calibration parameters determined and stored during process 1002 for that bracket. These parameters typically specify a new total charge pump current (Icp_new), as well as how many charge pump stages to enable and what per-unit current index (UIcp_Index) to use. By retrieving these parameters, the process avoids repeated real-time calculation and relies instead on the predetermined solutions verified via simulation or silicon characterization.

In one or more examples, process 1010, at operation 1022, may include applying the retrieved or determined calibration parameters to the PLL hardware, thus setting the number of CP stages and the per-unit current according to the LUT entry. The PLL is then switched back into closed-loop operation with the updated charge pump current, ensuring that it compensates for the measured VCO gain deviation. Once the loop is enabled, the system remains capable of stable, predictable bandwidth performance despite the underlying PVT variations.

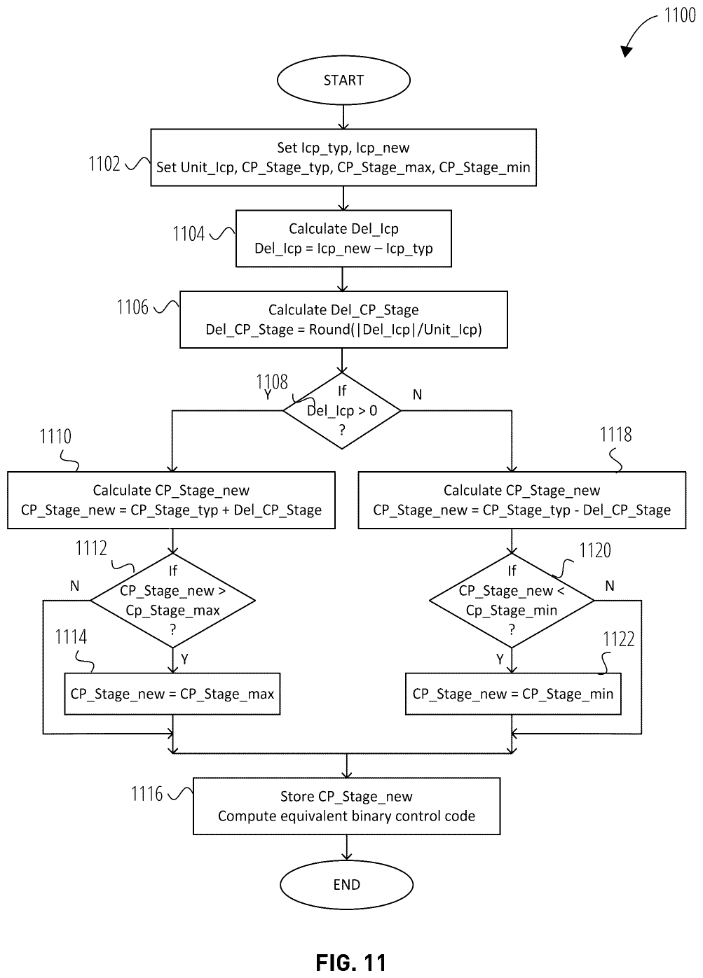

FIG. 11 is a flow diagram depicting a process 1100 for setting a new total charge pump current (Icp_new) and determining how many charge pump stages (CP_Stage_new) should be active to compensate for an observed difference between the measured or desired Icp value and a baseline value. This process assumes that the unit charge pump current (Unit_Icp) is fixed, and that adjustments are made by enabling or disabling discrete charge pump stages.

Although the example process 1100 depicts a particular sequence of operations, the sequence may be altered without departing from the scope of the present disclosure. For example, some of the operations depicted may be performed in parallel or in a different sequence that does not materially affect the function of the process 1100. In other examples, different components of an example device or system that implements the process 1100 may perform functions at substantially the same time or in a specific sequence.

In one or more examples, process 1100, at operation 1102, may include setting various initial parameters. The system identifies Icp_typ, which is the typical or baseline charge pump current, and Icp_new, which represents the newly determined or desired total current to compensate for a measured deviation in voltage-controlled oscillator (VCO) gain. The system also sets Unit_Icp, representing the fixed current per charge pump stage, along with CP_Stage_typ, CP_Stage_max, and CP_Stage_min, defining the typical, maximum, and minimum numbers of allowed charge pump stages, respectively.

In one or more examples, process 1100, at operation 1104, may include calculating Del_Icp by subtracting Icp_typ from Icp_new, resulting in a value that indicates how much the total current should increase or decrease. If Del_Icp is positive, it signifies that Icp_new exceeds Icp_typ, requiring more total current. Conversely, if Del_Icp is negative, the system reduces the number of active CP stages or otherwise lower the current to achieve Icp_new.

In one or more examples, process 1100, at operation 1106, may include deriving Del_CP_Stage by dividing Del_Icp by Unit_Icp and rounding the result to the nearest integer. This operation translates the difference in total current into a discrete number of charge pump stages to be added or removed from CP_Stage_typ.

In one or more examples, process 1100, at operations 1108, 1110, 1112, and 1114, may include branching to calculate CP_Stage_new (operation 1110) based on whether Del_Icp is greater than zero. If Del_Icp is greater than zero, at operation 1110, the system sets CP_Stage_new to CP_Stage_typ plus Del_CP_Stage, reflecting that more current is needed to reach Icp_new.

In one or more examples, process 1100, at operations 1112 and 1114, may include bounding CP_Stage_new to ensure it does not exceed CP_Stage_max; if CP_Stage_new is larger than CP_Stage_max, it is clamped.

In one or more examples, process 1100, at operations 1108, 1118, 1120, and 1122, may include an alternate branch for the case in which Del_Icp is not greater than zero (i.e., less than or equal to zero). At operation 1118, process 1100 may include setting CP_Stage_new to CP_Stage_typ minus Del_CP_Stage, reducing the number of enabled stages to match the lower current.

In one or more examples, process 1100, at operations 1120 and 1122, may include bounding CP_Stage_new to ensure it stays above CP_Stage_min; if CP_Stage_new is smaller than CP_Stage_min, the system clamps it to CP_Stage_min.

In one or more examples, process 1100, at operation 1116 (or the corresponding final block when Del_Icp≤0), may include storing the finalized CP_Stage_new value along with the total current Icp_new. The system also determines any necessary binary control code for enabling or disabling the specified number of CP stages in hardware registers. In some implementations, this finalization operation depends on whether CP_Stage_new was increased or decreased, but its overall function remains the same: the PLL now has updated charge pump parameters ready for closed-loop operation.

Once process 1100 concludes, the PLL can incorporate these updated settings—particularly CP_Stage_new and Icp_new—to offset a measured deviation in VCO gain or any other factor that caused Icp to shift from its baseline value. This ensures that the product of Icp and VCO gain remains near the target range, thereby maintaining stable closed-loop bandwidth despite process, supply voltage, and temperature variations.

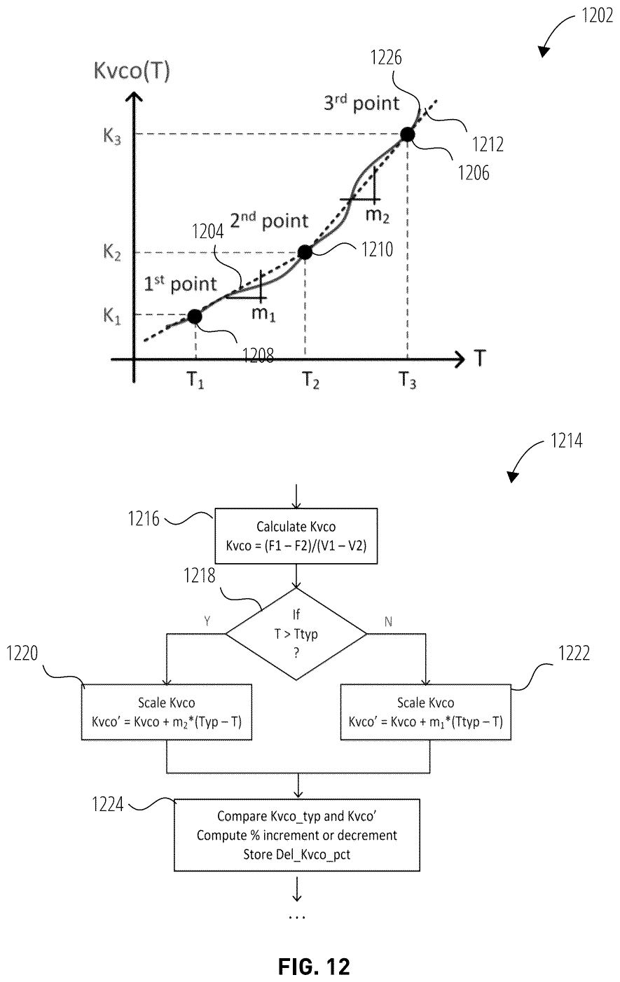

In one or more examples, FIG. 12 depicts is a conceptual diagram of a graph 1202 that illustrates how a non-linear temperature dependent VCO gain function, denoted Kvco(T) on the vertical axis, can be approximated by two linear segments when measured at three distinct temperature points T₁, T₂, and T₃ or Tmin, Ttyp or Tmax. By collecting three measurements—one at each temperature—the system can create a piecewise linear function that more accurately represents a non-linear Kvco(T) relationship than a single linear approximation. The non-linear Kvco(T) relationship may be used to predict and compensate for Kvco variations due to temperature drift.

In the specific non-limiting example depicted by FIG. 12, point 1208 corresponds to a first measured data point (K₁) at temperature T₁, point 1210 corresponds to a second measured data point (K₂) at temperature T₂, and point 1212 corresponds to a third measured data point (K₃) at temperature T₃. These three points define two linear segments: segment 1204 spans from T₁ to T₂, and segment 1206 spans from T₂ to T₃. The solid curve 1226 in graph 1202 represent the measured or “true” behavior of Kvco with respect to temperature; the two linear segments (1204 and 1206) together form a piecewise linear approximation used to model that behavior.

Because Kvco may be significantly non-linear across the complete temperature range, splitting the approximation into two segments-rather than forcing a single straight line enables a closer match between the measured points and the approximated function. This approach, referred to herein as a “3-point measurement,” captures more nuances of Kvco(T).

In one or more examples, respective measured data points (e.g., points 1208, 1210, and 1212, without limitation) may be obtained by placing the PLL or oscillator in a mode that allows for direct Kvco characterization at specific temperatures (e.g., an open loop measurement, without limitation). Once these three Kvco values (K₁, K₂, K₃) are acquired, the system determines slopes and offsets for each segment, storing the resulting piecewise parameters in, for example, an LUT. During normal operation, if the on-chip temperature monitor (TMON) indicates that the operating temperature lies between T₁ and T₂ or between T₂ and T₃, the PLL calibration engine selects the corresponding linear function to estimate Kvco at that temperature. Armed with this approximation, the engine can then adjust charge pump current (Icp) or other parameters to compensate for temperature-dependent Kvco drift, thereby maintaining a stable closed-loop bandwidth despite non-linear variations.

Utilizing a non-linear model—such as a piecewise linear approximation based on a three-point measurement or a higher-order polynomial approximation—allows the calibration engine to determine more precisely how much the actual Kvco deviates from its nominal or target value at a given operating temperature. This prediction is then used to calculate the necessary adjustment in the charge pump current (Icp) or other PLL parameters, such that the product Icp×Kvco remains constant.

FIG. 12 also includes a flow diagram depicting a process 1214 to determine a translated VCO gain (Kvco′) (e.g., temperature-scaled VCO gain (Kvco′), without limitation) and store the resulting gain deviation in a piecewise linear or multi-point context. In one or more examples, this flow leverages the fact that non-linear Kvco(T) behavior can be approximated by separate linear functions on different temperature intervals.

In one or more examples, the process 1214 at operation 1216 may include calculating Kvco by measuring the difference in output frequency (F₁−F₂) and dividing it by the difference in control voltage (V₁−V₂). This open-loop measurement provides a raw estimate of how sensitive the oscillator frequency is to the input voltage, denoted as Kvco.

In one or more examples, the process 1214, at operation 1218, may include comparing the actual temperature of the device T to a nominal or typical temperature Ttyp. If T is greater than Ttyp, the process 1214 proceeds to a different branch than if T is less than or equal to Ttyp, allowing the system to choose which linear approximation (i.e., slope) best captures the temperature dependence for that measured value.

In one or more examples, if T is determined to be greater than Ttyp, the process 1214 at operation 1220 may include scaling Kvco using a slope m₂ associated with a higher-than-nominal segment of the temperature response. This may be expressed as:

$${K}_{vco}^{′} = {K}_{vco} + {m}_{2} \times ( {T}_{typ} - T )$$

where T represents the current temperature, T_typ (also denoted herein as “Ttyp” or “Ttyp”) is a reference temperature, which may be a nominal or typical temperature; and m₂ is a slope or scaling factor derived through a three-point (or multi-point) measurement.

In one or more examples, if T is not greater than Ttyp, process 1214 may include, at operation 1222, where Kvco is translated (e.g., scaled, without limitation) with a different slope m₁ suited for a lower-than-nominal segment of the temperature curve. This may be expressed as:

$${K}_{vco}^{′} = {K}_{vco} + {m}_{1} \times ( {T}_{typ} - T )$$

resulting in a temperature-adjusted VCO gain that more accurately reflects the device's actual operating conditions.

In one or more examples, operation 1224 may include comparing the final translated Kvco′ (determined in either operation 1220 or operation 1222) to Kvco_typ, determining the difference, and storing the result as a percentage increment or decrement (Del_Kvco_pct). This value indicates how far the actual, temperature-corrected VCO gain departs from the nominal assumption. In one or more examples, Del_Kvco_pct is then used to adjust the PLL's charge pump current (Icp), such that the PLL bandwidth remains consistent across a range of temperatures.

In one or more examples, an alternate piecewise approach to computing the VCO gain deviation may be performed by applying the temperature-dependent scaling directly to the predetermined target gain, Kvco_typ, rather than to the measured Kvco. In such embodiments, when the measured temperature T exceeds the nominal temperature Ttyp, the system determines a translated target gain, Kvco_typ′, using the slope m₂ associated with the upper temperature segment according to:

$${Kvco\_typ}^{′} = Kvco\_typ + {m}_{2} \times ( T - Ttyp )$$

Conversely, when T is less than or equal to Ttyp, the system employs the slope m₁ for the lower temperature segment and determines:

$${Kvco\_typ}^{′} = Kvco\_typ + {m}_{1} \times ( T - Ttyp )$$

Once Kvco_typ′ has been determined in either case, the process calculates the deviation Del_Kvco_pct by comparing the raw measured gain Kvco to the adjusted target Kvco_typ′. Because Del_Kvco_pct=(Kvco−Kvco_typ′)/Kvco_typ′, this alternate formula yields the same percentage deviation as the previously described method of scaling the measured Kvco. The resulting Del_Kvco_pct may then be stored or looked up in the calibration table and used to drive adjustments to the PLL's charge pump current (Icp), so as to maintain a consistent loop bandwidth across the full temperature range. This dual formulation—scaling either the measured gain or the target gain—can be selected by a person of ordinary skill in the art based on system architecture, computational convenience, or calibration strategy, without departing from the scope of the present disclosure.

By tailoring which linear function (m₁ or m₂) is used for scaling Kvco based on the measured gain's relation to Kvco_typ, this flow diagram, graph 1202 (or FIG. 12) implements a piecewise linear approximation for Kvco(T). Coupled with multi-point data capture (e.g., measuring the device at T₁, T₂, T₃), and various examples accommodate non-linear Kvco behavior and achieve more precise calibration of PLL loop parameters than a single-slope, one-size-fits-all approach.

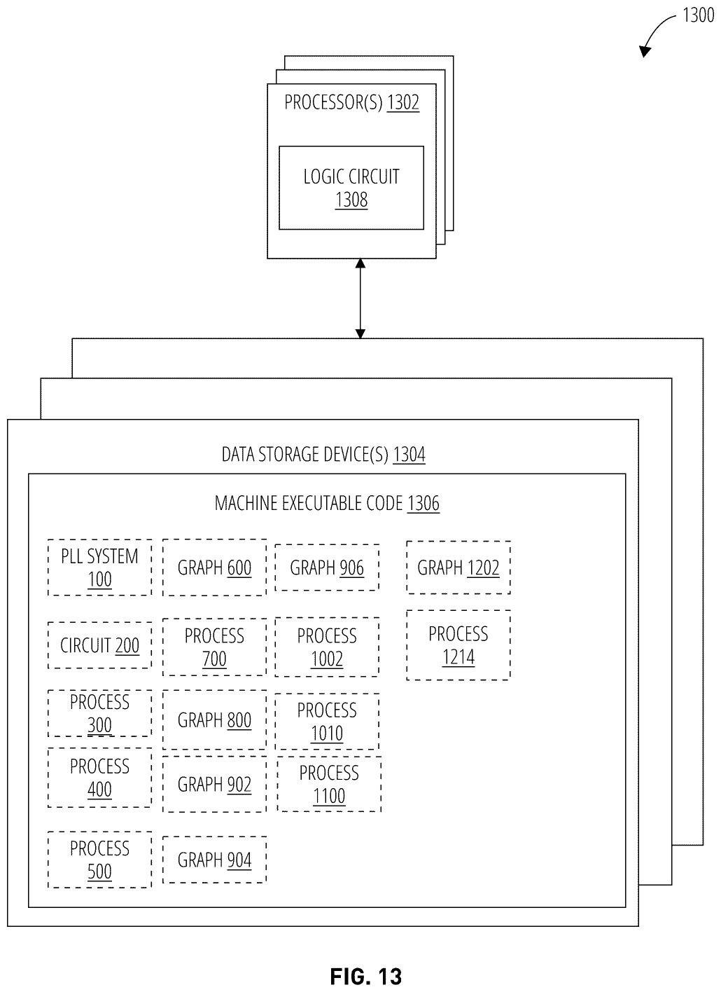

It will be appreciated by those of ordinary skill in the art that functional elements of examples disclosed herein (e.g., functions, operations, acts, processes, or methods) may be implemented in any suitable hardware, software, firmware, or combinations thereof. FIG. 13 illustrates non-limiting examples of implementations of functional elements disclosed herein. In some examples, some or all portions of the functional elements disclosed herein may be performed by hardware capable of carrying out the functional elements.

FIG. 13 is a block diagram of a circuitry 1300 that, in some examples, may be used to implement various functions, operations, acts, processes, or methods disclosed herein. The circuitry 1300 includes one or more processors 1302 (sometimes referred to herein as “processors 1302”) operably coupled to one or more data storage devices 1304 (sometimes referred to herein as “storage 1304”). The storage 1304 includes machine executable code 1306 stored thereon and the processors 1302 include logic circuit 1308. The machine executable code 1306 includes information describing functional elements that may be implemented by (e.g., performed by) the logic circuit 1308. The logic circuit 1308 is adapted to implement (e.g., perform) the functional elements described by the machine executable code 1306. The circuitry 1300, when executing the functional elements described by the machine executable code 1306, should be considered as special purpose hardware for carrying out functional elements disclosed herein. In one or more examples, the processors 1302 may perform the functional elements described by the machine executable code 1306 sequentially, concurrently (e.g., on one or more different hardware platforms), or in one or more parallel process streams.

When implemented by logic circuit 1308 of the processors 1302, the machine executable code 1306 adapts the processors 1302 to perform operations of examples disclosed herein. By way of non-limiting example, the machine executable code 1306 may adapt the processors 1302 to perform some or a totality of operations of one or more processes discussed herein, including one or more of those related to process 300, process 400, process 500, graph 600, process 700, graph 800, graph 902, graph 904, graph 906, process 1002, process 1010, process 1100, process 1100, graph 1202, process 1214, block diagram 1300, or graph 1400.

Also, by way of non-limiting example, the machine executable code 1306 may adapt the processors 1302 to perform some or a totality of features, functions, or operations disclosed herein with respect to PLL system 100 or circuit 200.

The processors 1302 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device (PLD), discrete gate or transistor logic, discrete hardware components, other programmable device, or any combination thereof designed to perform the functions disclosed herein. A general-purpose determiner including one or more processors 1302, including a general-purpose processor, is considered a special-purpose determiner at least while the general-purpose determiner executes functional elements corresponding to the machine executable code 1306 (e.g., software code, firmware code, configuration data, hardware descriptions, without limitation) related to examples of the present disclosure. It is noted that a general-purpose processor (which may also be referred to herein as a host processor or simply a host) may be a microprocessor, but in the alternative, a general-purpose processor of processors 1302 may include any conventional processor, controller, microcontroller, or state-machine. An FPGA or other PLD of the processors 1302 may be configured (e.g., programmed, without limitation) with configuration data to perform functions disclosed herein, or, additionally or alternatively, may be capable of being configured or re-configured (e.g., programmable, or re-programmable, without limitation) with configuration data to perform functions disclosed herein. The processors 1302 may also be implemented as a combination of computing devices, such as a combination of a DSP and a microprocessor, a plurality of microprocessors, one or more microprocessors in conjunction with a DSP core, or any other such configuration.

In one or more examples the storage 1304 includes volatile data storage (e.g., random-access memory (RAM), static RAM (SRAM), without limitation), non-volatile data storage (e.g., Flash memory, a hard disc drive, a solid-state drive, erasable programmable read-only memory (EPROM), without limitation). In some examples the processors 1302 and the storage 1304 may be implemented into a single device (e.g., a semiconductor device product, a system on chip (SOC), without limitation). In some examples the processors 1302 and the storage 1304 may be implemented into separate devices.

In one or more examples the machine executable code 1306 may include determiner-readable instructions (e.g., software code, firmware code). By way of non-limiting example, the determiner-readable instructions may be stored by the storage 1304, accessed directly by the processors 1302, and executed by the processors 1302 using at least the logic circuit 1308. Also, by way of non-limiting example, the determiner-readable instructions may be stored on the storage 1304, transferred to a memory device (not shown) for execution, and executed by the processors 1302 using at least the logic circuit 1308. Processors 1302 or logic circuit 1308 thereof be coupled to such a memory device or include such a memory device (e.g., a configuration memory cell, without limitation). Accordingly, in some examples the logic circuit 1308 includes electrically configurable logic circuit 1308.

In one or more examples the machine executable code 1306 may describe hardware (e.g., circuitry) to be implemented in the logic circuit 1308 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, Verilog, System Verilog or very-large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 1308 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples the machine executable code 1306 may include an HDL, an RTL, a GL description, a mask level description, other hardware description, or any combination thereof.

In examples where the machine executable code 1306 includes a hardware description (at any level of abstraction), a system (not shown, but including the storage 1304) implements the hardware description described by the machine executable code 1306. By way of non-limiting example, the processors 1302 may include a programmable logic device (e.g., an FPGA or a PLC, without limitation) and the logic circuit 1308 may be electrically controlled (e.g., via configuration data, without limitation) to implement circuitry corresponding to the hardware description into the logic circuit 1308. Also, by way of non-limiting example, the logic circuit 1308 may include hard-wired logic manufactured by a manufacturing system (not shown, but including the storage 1304) according to the hardware description of the machine executable code 1306.

Regardless of whether the machine executable code 1306 includes determiner-readable instructions or a hardware description, the logic circuit 1308 is adapted to perform the functional elements described by the machine executable code 1306 when implementing the functional elements of the machine executable code 1306. It is noted that although a hardware description may not directly describe functional elements, a hardware description indirectly describes functional elements that the hardware elements described by the hardware description are capable of performing.

Below are definitions of at least some of the acronyms used in the specification and accompanying figures:
PLL—Phase Locked Loop
VCO—Voltage Controlled Oscillator
VT—Voltage and Temperature
PVT—Process, Supply Voltage and Temperature
LC—Inductor & Capacitor
Q—Quality Factor, e.g., for LC
BW—Bandwidth
CLBW—Closed loop Bandwidth
CAL—Calibration
G_{L}—PLL open loop Gain
VMON—Voltage Monitor
TMON—Temperature Monitor
Si-Char—Silicon Characterization
Sim—Simulation
LUT—Look-Up Table
Vcontrol—Control Voltage, e.g., for a VCO
DAC—Digital to Analog Converter
LPF—Low Pass Filter
PFD—Phase & Frequency Detector
CP—Charge Pump
BB PD—Bang—Bang Phase Detector
SERDES—SERializer and DESerializer
Kvco—VCO gain or Del Freq/Del Vcontrol
Del_Kvco_pct—Difference between measured Kvco and Kvco typical in percentage
Icp—Total charge pump current
CP_Stage—Number of parallel charge pump stages
CP_Stage_max—Max available number of parallel charge pump stages
CP_Stage_min—Min available number of parallel charge pump stages
CP_Stage_new—New setting for parallel charge pump stages after the BW calibration
Unit_Icp—One unit charge pump current
Del_Icp—Difference between New Icp target and Icp typical
UIcp_Index—Pointer for Unit_Icp array or it selects one of the programmable Unit_Icp values.
UIcp_Index_max—Max setting for UIcp_Index pointer
UIcp_Index_min—Min setting for UIcp_Index pointer

As used in the present disclosure, the terms “module” or “component” may refer to specific hardware implementations to perform the actions of the module or component and/or software objects or software routines that may be stored on and/or executed by general purpose hardware (e.g., determiner-readable media, processing devices, without limitation) of the computing system. In some examples, the different components, modules, engines, and services described in the present disclosure may be implemented as objects or processes that execute on the computing system (e.g., as separate threads). While some of the systems and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:

Example 1: An apparatus, comprising: a phase-locked loop (PLL) circuit; and a logic circuit to manage, via one or more programmable operating parameters of the PLL circuit, PLL bandwidth variation exhibited by the PLL circuit, due to variations in its manufacturing process (P), supply voltage (V) or temperature (T), i.e., PVT variations exhibited by the PLL circuit.

Example 2: The apparatus according to Example 1, wherein the programmable operating parameters of the PLL circuit comprise one or more of: a total charge pump current, a unit charge pump current, a number of active charge pump stages, or a reference voltage Vref of the PLL circuit.

Example 3: The apparatus according to any of Examples 1 and 2, wherein the logic circuit to set one or more of the programmable operating parameters during open-loop operation of the PLL circuit.

Example 4: The apparatus according to any of Examples 1 through 3, wherein the logic circuit to: measure a parameter indicative of voltage-controlled oscillator (VCO) gain (Kvco); determine a deviation of Kvco from target at least partially based on a comparison of the measured parameter and a predetermined target Kvco; and set one or more of the programmable operating parameters at least partially based on the determined deviation.

Example 5: The apparatus according to any of Examples 1 through 4, wherein the logic circuit to: determine a value for total charge pump current at least partially based on the determined deviation of Kvco from target; and set the one or more parameters of the PLL circuit at least partially based on the determined value.

Example 6: The apparatus according to any of Examples 1 through 5, wherein the logic circuit to determine the value for total charge pump current at least partially based on a lookup table, wherein data of the look up table correlates ranges of deviation of Kvco from target with corresponding charge pump settings that determine total charge pump current.

Example 7: The apparatus according to any of Examples 1 through 6, wherein the data of the look up table includes values for a unit charge pump current and a number of active charge pump stages needed to achieve the target total charge pump current.

Example 8: The apparatus according to any of Examples 1 through 7, wherein the logic circuit to employ an iterative algorithm to determine one or more programmable operating parameters, wherein the iterative algorithm adjusts the number of active charge pump stages and the unit charge pump current until a product of these parameters approximates a determined value for total charge pump current.

Example 9: The apparatus according to any of Examples 1 through 8, wherein the logic circuit to: determine a value for nominal total charge pump current; and determine the value for total charge pump current based on the determined value for nominal total charge pump current and a scaling factor.

Example 10: The apparatus according to any of Examples 1 through 9, wherein the logic circuit to determine the value for nominal total charge pump current as a product of a predetermined unit charge pump current derived from a reference voltage, Vref and a predetermined number of charge pump stages.

Example 11: The apparatus according to any of Examples 1 through 10, wherein the scaling factor is at least partially based on the determined deviation of Kvco from target.

Example 12: The apparatus according to any of Examples 1 through 11, wherein the logic circuit to: translate the measured parameter at least partially based on a predetermined relationship between Kvco and temperature or supply voltage; and utilize the translated measured parameter to determine the deviation of Kvco from target value to account for worst-case post calibration VT drift.

Example 13: The apparatus according to any of Examples 1 through 12, wherein the predetermined relationship is determined from simulation data and/or silicon characterization and stored in a lookup table, and wherein the logic circuit to use the lookup table to translate the measured parameter according to start-up temperature or supply voltage.

Example 14: The apparatus according to any of Examples 1 through 13, wherein the predetermined relationship is determined based on production test data by employing a two-point or three-point measurement technique to approximate nonlinear behavior of Kvco over a temperature range or supply voltage range and the resultant relationship is stored in a lookup table, and wherein the logic circuit to use the lookup table to translate the measured parameter according to start-up temperature or supply voltage.

Example 15: The apparatus according to any of Examples 1 through 14, wherein the predetermined relationship between Kvco and temperature or supply voltage is approximated as a linear function.

Example 16: The apparatus according to any of Examples 1 through 15, wherein a linear function is represented by the equation Kvco(T)=m₁×T+c₁ or Kvco(V)=m₂×T+c₂, where m₁ and m₂ are slopes representing a rate of change of Kvco with temperature or supply voltage, and c₁ and c₂ are intercepts representing the nominal gain at a reference temperature or supply voltage, respectively.

Example 17: The apparatus according to any of Examples 1 through 16, wherein the predetermined relationship between Kvco and temperature or supply voltage is approximated as a nonlinear function comprising a second-order polynomial.

Example 18: The apparatus according to any of Examples 1 through 17, wherein the second-order polynomial is represented by the equation Kvco(T)=a₂×T²+a₁×T+a₀ or Kvco(V)=b₂×V₂+b₁×V+b₀, wherein a₂, a₁, a₀ and b₂, b₁, b₀ are coefficients determined from characterization data that reflect temperature-dependent or supply voltage dependent behavior of Kvco respectively.

Example 19: The apparatus according to any of Examples 1 through 18, wherein the PLL circuit is operable in an open-loop mode and a closed-loop mode, and wherein the logic circuit, during the open-loop mode of the PLL circuit, to: set a VCO control voltage to at least two different voltage levels; measure corresponding oscillator frequencies; and determine the parameter indicative of Kvco at least partially based on at least two different voltage levels and corresponding oscillator frequencies.

Example 20: The apparatus according to any of Examples 1 through 19, wherein the logic circuit to determine the one or more programmable operating parameters at least partially based on a lookup table comprising predetermined settings of the programmable operating parameters of the PLL circuit.

Example 21: The apparatus according to any of Examples 1 through 20, wherein the predetermined settings corresponding to various ranges of VCO gain deviation, and wherein the logic circuit selects settings from the lookup table based on a measured VCO gain deviation.

Example 22: The apparatus according to any of Examples 1 through 21, wherein the one or more programmable operating parameters include a reference voltage (Vref) for the PLL circuit, and wherein the logic circuit to adjust Vref to further manage PLL bandwidth variation in response to changes in VCO gain.

Example 23: The apparatus according to any of Examples 1 through 22, wherein the PLL circuit includes a digital proportional controller, and the logic circuit is integrated with the digital proportional controller.

Example 24: The apparatus according to any of Examples 1 through 23, wherein the logic circuit to: measure a voltage-controlled oscillator (VCO) gain Kvco at three distinct temperatures T₁, T₂, T₃ or supply voltages V₁, V₂, V₃ and to generate first, second, and third measured gains K₁, K₂, K₃ at the respective temperatures or supply voltages; form a piecewise linear approximation of Kvco(T) or Kvco(V) by defining a first linear function between temperatures T₁ and T₂ or supply voltages V₁ and V₂ and a second linear function between temperatures T₂ and T₃ or supply voltages V₂ and V₃; select one of the first or second linear functions based on a measured temperature or supply voltage to scale a measured Kvco; and generate a temperature-compensated or supply voltage-compensated version of measured Kvco at least partially based on the selected one of the first or second linear functions; and determine a deviation of Kvco from target value at least partially based on a comparison of the temperature-compensated or supply voltage-compensated version of measured Kvco and a predetermined target Kvco; and determine one or more of the programmable operating parameters of the PLL circuit at least partially based on the determined deviation.

Example 25: The apparatus according to any of Examples 1 through 24, wherein the logic circuit to store the first and second linear functions in a look up table with their respective temperature or supply voltage ranges.

Example 26: A method, comprising: operating a PLL circuit having one or more programmable operating parameters; measuring a parameter indicative of PLL bandwidth variation; and setting one or more of the programmable operating parameters of the PLL circuit at least partially based on a determined deviation of the measured parameter to a predetermined target value.

Example 27: The method according to Example 26, wherein measuring the parameter indicative of PLL bandwidth variation comprises measuring a parameter indicative of voltage-controlled oscillator (VCO) gain (Kvco).

Example 28: The method according to any of Examples 26 and 27, comprising comparing a measured VCO gain to a predetermined target VCO gain, and determining a deviation between the measured VCO gain and the target VCO gain.

Example 29: The method according to any of Examples 26 through 28, comprising: determining a value for a total charge pump current based at least partially on the determined deviation of VCO gain, wherein the total charge pump current is calculated as a product of a programmable unit charge pump current and a programmable number of active charge pump stages.

Example 30: The method according to any of Examples 26 through 29, comprising: retrieving from a lookup table a set of charge pump calibration settings, wherein the lookup table correlates ranges of VCO gain deviation from the target with corresponding settings for the unit charge pump current and the number of active charge pump stages, and setting the programmable operating parameters of the PLL circuit based on the retrieved settings.

Example 31: The method according to any of Examples 26 through 30, wherein setting one or more of the programmable operating parameters comprises: utilizing an iterative algorithm that adjusts the number of active charge pump stages and the programmable unit charge pump current until a product of these parameters approximates a target total charge pump current determined based on the deviation of the measured VCO gain from the target.

Example 32: The method according to any of Examples 26 through 31, comprising determining a nominal total charge pump current as a product of a predetermined unit charge pump current—derived from a reference voltage (Vref)—and a predetermined number of charge pump stages, and then determining the total charge pump current by applying a scaling factor based on the measured deviation of VCO gain from the target.

Example 33: The method according to any of Examples 26 through 32, wherein measuring the parameter indicative of PLL bandwidth variation comprises: changing a measured VCO gain parameter based at least partially on a predetermined relationship between VCO gain and temperature or supply voltage, and utilizing a temperature-translated or supply voltage-translated measured parameter to determine the deviation of VCO gain from the target to account for worst-case post calibration VT drift.

Example 34: The method according to any of Examples 26 through 33, wherein the predetermined relationship between VCO gain and temperature or supply voltage is determined from simulation data or silicon characterization and stored in a lookup table, and

wherein a logic of the method uses the lookup table to adjust the measured parameter according to an operating temperature or supply voltage.

Example 35: The method according to any of Examples 26 through 34, wherein the predetermined relationship between VCO gain and temperature or supply voltage is determined based on production test data by employing a two-point or three-point measurement technique to approximate nonlinear behavior of VCO gain over a temperature or supply voltage range, and wherein the resultant relationship is stored in a lookup table for use in adjusting the measured parameter.

Example 36: The method according to any of Examples 26 through 35, wherein the predetermined relationship between VCO gain and temperature or supply voltage is expressed as a linear function.

Example 37: The method according to any of Examples 26 through 36, wherein the predetermined relationship between VCO gain and temperature or supply voltage is expressed as a nonlinear function comprising a second-order polynomial.

Example 38: The method according to any of Examples 26 through 37, comprising operating the PLL circuit in an open-loop mode during calibration, wherein the method sets a VCO control voltage to at least two different levels, measures the corresponding oscillator frequencies, and determines a parameter indicative of VCO gain from these measurements.

Example 39: The method according to any of Examples 26 through 38, comprising adjusting a reference voltage (Vref) of the PLL circuit as one of the programmable operating parameters to further manage PLL bandwidth variation in response to changes in VCO gain.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus, comprising:
a phase-locked loop (PLL) circuit; and
a logic circuit to manage, via one or more programmable operating parameters of the PLL circuit, PLL bandwidth variation exhibited by the PLL circuit, due to variations in its manufacturing process (P), supply voltage (V) or temperature (T), i.e., PVT variations exhibited by the PLL circuit.

2. The apparatus of claim 1, wherein the programmable operating parameters of the PLL circuit comprise one or more of: a total charge pump current, a unit charge pump current, a number of active charge pump stages, or a reference voltage Vref of the PLL circuit.

3. The apparatus of claim 1, wherein the logic circuit to set one or more of the programmable operating parameters during open-loop operation of the PLL circuit.

4. The apparatus of claim 1, wherein the logic circuit to:
measure a parameter indicative of voltage-controlled oscillator (VCO) gain (Kvco);
determine a deviation of Kvco from target at least partially based on a comparison of the measured parameter and a predetermined target Kvco; and
set one or more of the programmable operating parameters at least partially based on the determined deviation.

5. The apparatus of claim 4, wherein the logic circuit to:
determine a value for total charge pump current at least partially based on the determined deviation of Kvco from target; and
set the one or more parameters of the PLL circuit at least partially based on the determined value.

6. The apparatus of claim 5, wherein the logic circuit to determine the value for total charge pump current at least partially based on a lookup table, wherein data of the look up table correlates ranges of deviation of Kvco from target with corresponding charge pump settings that determine total charge pump current.

7. The apparatus of claim 6, wherein the data of the look up table includes values for a unit charge pump current and a number of active charge pump stages needed to achieve the target total charge pump current.

8. The apparatus of claim 2, wherein the logic circuit to employ an iterative algorithm to determine one or more programmable operating parameters, wherein the iterative algorithm adjusts the number of active charge pump stages and the unit charge pump current until a product of these parameters approximates a determined value for total charge pump current.

9. The apparatus of claim 5, wherein the logic circuit to:
determine a value for nominal total charge pump current; and
determine the value for total charge pump current based on the determined value for nominal total charge pump current and a scaling factor.

10. The apparatus of claim 9, wherein the logic circuit to determine the value for nominal total charge pump current as a product of a predetermined unit charge pump current derived from a reference voltage, Vref and a predetermined number of charge pump stages.

11. The apparatus of claim 9, wherein the scaling factor is at least partially based on the determined deviation of Kvco from target.

12. The apparatus of claim 4, wherein the logic circuit to:
translate the measured parameter at least partially based on a predetermined relationship between Kvco and temperature or supply voltage; and
utilize the translated measured parameter to determine the deviation of Kvco from target value to account for worst-case post calibration VT drift.

13. The apparatus of claim 12, wherein the predetermined relationship is determined from simulation data and/or silicon characterization and stored in a lookup table, and wherein the logic circuit to use the lookup table to translate the measured parameter according to start-up temperature or supply voltage.

14. The apparatus of claim 12, wherein the predetermined relationship is determined based on production test data by employing a two-point or three-point measurement technique to approximate nonlinear behavior of Kvco over a temperature range or supply voltage range and the resultant relationship is stored in a lookup table, and wherein the logic circuit to use the lookup table to translate the measured parameter according to start-up temperature or supply voltage.

15. The apparatus of claim 12, wherein the predetermined relationship between Kvco and temperature or supply voltage is approximated as a linear function.

16. The apparatus of claim 12, wherein a linear function is represented by the equation Kvco(T)=m₁×T+c₁ or Kvco(V)=m₂×T+c₂, where m₁ and m₂ are slopes representing a rate of change of Kvco with temperature or supply voltage, and c₁ and c₂ are intercepts representing the nominal gain at a reference temperature or supply voltage, respectively.

17. The apparatus of claim 12, wherein the predetermined relationship between Kvco and temperature or supply voltage is approximated as a nonlinear function comprising a second-order polynomial.

18. The apparatus of claim 17, wherein the second-order polynomial is represented by the equation Kvco(T)=a₂×T²+a₁×T+a₀ or Kvco(V)=b₂×V²+b₁×V+b₀, wherein a₂, a₁, a₀ and b₂, b₁, b₀ are coefficients determined from characterization data that reflect temperature-dependent or supply voltage dependent behavior of Kvco respectively.

19. The apparatus of claim 4, wherein the PLL circuit is operable in an open-loop mode and a closed-loop mode, and wherein the logic circuit, during the open-loop mode of the PLL circuit, to:
set a VCO control voltage to at least two different voltage levels;
measure corresponding oscillator frequencies; and
determine the parameter indicative of Kvco at least partially based on at least two different voltage levels and corresponding oscillator frequencies.

20. The apparatus of claim 4, wherein the logic circuit to determine the one or more programmable operating parameters at least partially based on a lookup table comprising predetermined settings of the programmable operating parameters of the PLL circuit.

21. The apparatus of claim 20, wherein the predetermined settings corresponding to various ranges of VCO gain deviation, and wherein the logic circuit selects settings from the lookup table based on a measured VCO gain deviation.

22. The apparatus of claim 1, wherein the one or more programmable operating parameters include a reference voltage (Vref) for the PLL circuit, and wherein the logic circuit to adjust Vref to further manage PLL bandwidth variation in response to changes in VCO gain.

23. The apparatus of claim 1, wherein the PLL circuit includes a digital proportional controller, and the logic circuit is integrated with the digital proportional controller.

24. The apparatus of claim 1, wherein the logic circuit to:
measure a voltage-controlled oscillator (VCO) gain Kvco at three distinct temperatures T₁, T₂, T₃ or supply voltages V₁, V₂, V₃ and to generate first, second, and third measured gains K₁, K₂, K₃ at the respective temperatures or supply voltages;
form a piecewise linear approximation of Kvco(T) or Kvco(V) by defining a first linear function between temperatures T₁ and T₂ or supply voltages V₁ and V₂ and a second linear function between temperatures T₂ and T₃ or supply voltages V₂ and V₃;
select one of the first or second linear functions based on a measured temperature or supply voltage to scale a measured Kvco; and
generate a temperature-compensated or supply voltage-compensated version of measured Kvco at least partially based on the selected one of the first or second linear functions; and
determine a deviation of Kvco from target value at least partially based on a comparison of the temperature-compensated or supply voltage-compensated version of measured Kvco and a predetermined target Kvco; and
determine one or more of the programmable operating parameters of the PLL circuit at least partially based on the determined deviation.

25. The apparatus of claim 24, wherein the logic circuit to store the first and second linear functions in a look up table with their respective temperature or supply voltage ranges.

26. A method, comprising:
operating a PLL circuit having one or more programmable operating parameters;
measuring a parameter indicative of PLL bandwidth variation; and
setting one or more of the programmable operating parameters of the PLL circuit at least partially based on a determined deviation of the measured parameter to a predetermined target value.

27. The method of claim 26, wherein measuring the parameter indicative of PLL bandwidth variation comprises measuring a parameter indicative of voltage-controlled oscillator (VCO) gain (Kvco).

28. The method of claim 27, comprising comparing a measured VCO gain to a predetermined target VCO gain, and determining a deviation between the measured VCO gain and the target VCO gain.

29. The method of claim 28, comprising: determining a value for a total charge pump current based at least partially on the determined deviation of VCO gain, wherein the total charge pump current is calculated as a product of a programmable unit charge pump current and a programmable number of active charge pump stages.

30. The method of claim 29, comprising: retrieving from a lookup table a set of charge pump calibration settings, wherein the lookup table correlates ranges of VCO gain deviation from the target with corresponding settings for the unit charge pump current and the number of active charge pump stages, and setting the programmable operating parameters of the PLL circuit based on the retrieved settings.

31. The method of claim 29, wherein setting one or more of the programmable operating parameters comprises: utilizing an iterative algorithm that adjusts the number of active charge pump stages and the programmable unit charge pump current until a product of these parameters approximates a target total charge pump current determined based on the deviation of the measured VCO gain from the target.

32. The method of claim 28, comprising determining a nominal total charge pump current as a product of a predetermined unit charge pump current—derived from a reference voltage (Vref)—and a predetermined number of charge pump stages, and then determining the total charge pump current by applying a scaling factor based on the measured deviation of VCO gain from the target.

33. The method of claim 26, wherein measuring the parameter indicative of PLL bandwidth variation comprises: changing a measured VCO gain parameter based at least partially on a predetermined relationship between VCO gain and temperature or supply voltage, and utilizing a temperature-translated or supply voltage-translated measured parameter to determine the deviation of VCO gain from the target to account for worst-case post calibration VT drift.

34. The method of claim 33, wherein the predetermined relationship between VCO gain and temperature or supply voltage is determined from simulation data or silicon characterization and stored in a lookup table, and wherein a logic of the method uses the lookup table to adjust the measured parameter according to an operating temperature or supply voltage.

35. The method of claim 33, wherein the predetermined relationship between VCO gain and temperature or supply voltage is determined based on production test data by employing a two-point or three-point measurement technique to approximate nonlinear behavior of VCO gain over a temperature or supply voltage range, and wherein the resultant relationship is stored in a lookup table for use in adjusting the measured parameter.

36. The method of claim 33, wherein the predetermined relationship between VCO gain and temperature or supply voltage is expressed as a linear function.

37. The method of claim 33, wherein the predetermined relationship between VCO gain and temperature or supply voltage is expressed as a nonlinear function comprising a second-order polynomial.

38. The method of claim 26, comprising operating the PLL circuit in an open-loop mode during calibration, wherein the method sets a VCO control voltage to at least two different levels, measures the corresponding oscillator frequencies, and determines a parameter indicative of VCO gain from these measurements.

39. The method of claim 26, comprising adjusting a reference voltage (Vref) of the PLL circuit as one of the programmable operating parameters to further manage PLL bandwidth variation in response to changes in VCO gain.
